(19) United States
(12) Patent Application Publication
(10) Pub. No.: US 2014/0103292 A1
(43) Pub. Date: Apr. 17, 2014

(54) GALLIUM NITRIDE-BASED COMPOUND SEMICONDUCTOR LIGHT-EMITTING DEVICE AND LIGHT SOURCE APPARATUS USING THE DEVICE

(71) Applicant: Panasonic Corporation, Osaka (JP)

(72) Inventors: Shunji YOSHIDA, Kyoto (JP); Ryou KATO, Osaka (JP); Toshiya YOKOGAWA, Nara (JP)

(73) Assignee: Panasonic Corporation, Osaka (JP)

(21) Appl. No.: 14/109,286

(22) Filed: Dec. 17, 2013

Related U.S. Application Data
(63) Continuation of application No. PCT/JP2012/004657, filed on Jul. 23, 2012.

(30) Foreign Application Priority Data
Sep. 20, 2011 (JP) 2011-204524

(51) Int. Cl. H01L 33/32; H01L 33/50; H01L 33/06

(52) U.S. Cl. CPC H01L 33/32; H01L 33/06; H01L 33/50
USPC 257/13; 257/103; 257/98

(57) ABSTRACT

A gallium nitride-based compound semiconductor light-emitting device formed of nitride semiconductor expressed by a general expression AlₓIn_{y}Ga_{z}N, where 0≦x<1, 0<y<1, 0<z<1, and x+y+z=1. The device includes a light-emitting layer having a growth surface of a non-polar plane or a semi-polar plane. A growth surface of the nitride semiconductor has two anisotropic axes. An In composition of the nitride semiconductor has distribution changing along a first axis of the two axes. An interface between a region with a low In composition and a region with a high In composition is inclined from a plane perpendicular to the first axis toward the growth surface of the nitride semiconductor.

### CROSS-REFERENCE TO RELATED APPLICATIONS

This is a continuation of International Application No. PCT/JP2012/004657 filed on Jul. 23, 2012, which claims priority to Japanese Patent Application No. 2011-204524 filed on Sep. 20, 2011. The entire disclosures of these applications are incorporated by reference herein.

### BACKGROUND

The present disclosure relates to gallium nitride-based compound semiconductor light-emitting devices and light source apparatuses using the devices.

Nitride semiconductor containing nitrogen (N) being a Group V element is highly expected as a material of short-wavelength light-emitting devices because of its wide bandgap. Out of nitride semiconductor, gallium nitride-based compound semiconductor (i.e., GaN-based semiconductor) is actively researched. Blue light-emitting diode (LED) devices, green LED devices, and semiconductor laser devices formed of GaN-based semiconductor are put to practical use.

GaN-based semiconductor has a wurtzite crystal structure. FIG. 1 schematically illustrates a unit lattice of GaN crystal. At least part of Ga shown in FIG. 1 is substituted by Al or In in compound semiconductor crystal expressed by the general expression AlₐGa_{b}In_{c}N, where 0≦a, b, c≦1, and a+b+c=1.

FIG. 2 shows four fundamental vectors a₁, a₂, a₃, and c commonly used to express plane orientations of the wurtzite crystal structure by four index notation (hexagonal indexing).

The fundamental vector c extends in a [0001] direction. The axis extending in the direction is referred to as a “c-axis.” The plane perpendicular to the c-axis is referred to as a “c-plane” or a “(0001) plane.” The “c-axis” and the “c-plane” are also expressed by a “C-axis” and a “C-plane.”

As shown in FIGS. 3A-3D, the wurtzite crystal structure has not only the c-plane but also other representative crystal plane orientations. FIG. 3A represents the (0001) plane. FIG. 3B represents a (10-10) plane. FIG. 3C represents a (11-20) plane. FIG. 3D represents a (10-12) plane. In this specification, the sign “-,” which is applied to the left side of each number in brackets representing the Miller's index, means the inversion of the index for convenience. The signs “-” and correspond to bars in the drawings. The (0001) plane, the (10-10) plane, the (11-20) plane, and the (10-12) plane are also referred to as the c-plane, an m-plane, an a-plane, and an r-plane, respectively. The m-plane and the a-plane are non-polar planes parallel to the c-axis. The r-plane is a semi-polar plane. The m-plane is a general term for the (10-10) plane, a (-1010) plane, a (1-100) plane, a (-1100) plane, a (01-10) plane, and a (0-110) plane.

Conventionally, GaN-based semiconductor light-emitting devices have been fabricated by “c-plane growth.” In this specification, the term “X-plane growth” represents epitaxial growth in a direction perpendicular to the X-plane, where X is c, m, a, r, etc., of the hexagonal wurtzite structure. In the X-plane growth, the X-plane may also be referred to as a “growth surface.” A semiconductor layer formed by the X-plane growth may be referred to as an “X-plane semiconductor layer.”

In fabricating a light-emitting device having a semiconductor multilayer structure formed by the c-plane growth, spontaneous polarization occurs on the c-plane in a −c-direction (at the N-plane side) due to positional shift of Ga atoms and N atoms in the c-axis. On the other hand, in an InGaN quantum well layer used as a light-emitting layer, piezoelectric polarization occurs in a +c-direction (at the Ga-plane side) due to strain, thereby causing a quantum-confined Stark effect of carriers. The c-plane is thus referred to as a “polar plane.” This effect reduces the rate of radiative recombination of the carriers inside the light-emitting layer, thereby reducing the internal quantum efficiency. This increases the threshold current in the semiconductor laser device. In an LED device, the power consumption increases and the luminous efficiency decreases. In addition, as the density of the injected carriers increases, screening of the piezoelectric field occurs, thereby changing the emission wavelength.

In recent years, techniques of fabricating GaN-based semiconductor using the non-polar plane such as the m-plane and the a-plane, and the semi-polar plane such as the r-plane, a (11-22) plane, and a (20-21) plane as growth surfaces have been actively researched. If the non-polar plane can be selected as the growth surface, no polarization occurs in the thickness direction of the light-emitting layer (i.e., the direction of the crystal growth), thereby causing no quantum-confined Stark effect. As a result, light-emitting devices with potentially high efficiency can be fabricated. Where the semi-polar plane is selected as the growth surface, contribution of the quantum-confined Stark effect can be largely reduced.

FIG. 4A schematically illustrates the crystal structure of GaN-based semiconductor having the m-plane as the upper surface (i.e., the growth surface) in the cross-section (i.e., the cross-section perpendicular to the substrate plane). The Ga atoms and the N atoms exist along the same atom plane parallel to the m-plane. Thus, no polarization occurs in the direction perpendicular to the m-plane. The added In and Al are located in the Ga sites and substitute Ga. Even if at least part of Ga is substituted by In or Al, no polarization occurs in the direction perpendicular to the m-plane.

For your reference, FIG. 4B schematically illustrates the crystal structure of GaN-based semiconductor having the c-plane as the upper surface (i.e., the growth surface) in the cross-section (i.e., the cross-section perpendicular to the substrate plane). The Ga atoms and the N atoms do not exist along the same atom plane parallel to the m-plane. As a result, polarization occurs in the direction perpendicular to the c-plane. A GaN-based substrate having the c-plane as a principal surface is generally used for growing GaN-based semiconductor crystal. The positions of a Ga (or In) atom layer parallel to the c-plane, and a nitrogen atom layer are slightly shifted in the c-axis direction, thereby generating the polarization along the c-axis.

In fabricating GaN-based semiconductor using a non-polar plane or a semi-polar plane as the growth surface, oxygen tends to be incorporated as compared to the c-plane growth (see, for example, International Patent Publication No. WO 2011/058682). If oxygen is incorporated as impurities in an active layer, the incorporated oxygen serves as a non-luminescent center to reduce the luminous efficiency of the light-emitting device.

### SUMMARY

In the conventional techniques, there has been a demand for further improving the luminous efficiency of gallium nitride-based compound semiconductor light-emitting devices.

In view of the foregoing, the present disclosure was made. It is an objective of the present disclosure to improve the luminous efficiency of a gallium nitride-based compound semiconductor light-emitting device.

In order to achieve the objective, a gallium nitride-based compound semiconductor light-emitting device according to an aspect of the present disclosure is formed of nitride semiconductor expressed by a general expression AlₓIn_{y}Ga_{z}N, where 0≦x≦1, 0<y<1, 0<z<1, and x+y+z=1. The device includes a light-emitting layer having a growth surface of a non-polar plane or a semi-polar plane. A growth surface of the nitride semiconductor has two anisotropic axes. An In composition of the nitride semiconductor has distribution changing along a first axis of the two axes. An interface between a region with a low In composition and a region with a high In composition is inclined from a plane perpendicular to the first axis toward the growth surface.

The gallium nitride-based compound semiconductor light-emitting device according to the present disclosure largely improves the luminous efficiency of an active layer.

### BRIEF DESCRIPTION OF THE DRAWINGS

FIG. 1 is a schematic perspective view illustrating a unit lattice of gallium nitride (GaN) crystal.

FIG. 2 is a perspective view illustrating fundamental vectors a₁, a₂, a₃, and c of a wurtzite crystal structure.

FIGS. 3A-3D are schematic view illustrating representative crystal plane orientations of a hexagonal wurtzite structure.

FIG. 4A is a schematic view illustrating the crystal structure of GaN along the m-plane.

FIG. 4B is a schematic view illustrating the crystal structure of GaN along the c-plane.

FIG. 5 is a schematic cross-sectional view illustrating an InGaN layer grown beyond the critical thickness for illustration of the concept of the present disclosure.

FIGS. 6A and 6B are graphs for illustration of the concept of the present disclosure. FIG. 6A illustrates a result of reciprocal lattice mapping of symmetric reflection when an X ray is incident in the c-axis direction, on an InGaN layer grown beyond the critical thickness. FIG. 6B illustrates a result of reciprocal lattice mapping of symmetric reflection when an X ray is incident in the a-axis direction, on an InGaN layer grown beyond the critical thickness.

FIGS. 7A and 7B are cross-sectional views for illustration of the concept of the present disclosure. FIG. 7A schematically illustrates the state of lattice match between a substrate and an InGaN layer when an X ray is incident in the c-axis direction, on the InGaN layer grown beyond the critical thickness. FIG. 7B schematically illustrates the state of lattice match between a substrate and an InGaN layer when an X ray is incident in the a-axis direction, on the InGaN layer grown beyond the critical thickness.

FIG. 8 is a transmission electron microscopic (TEM) image for illustration of the concept of the present disclosure.

FIG. 9 is a schematic perspective view for illustration of the concept of the present disclosure.

FIG. 10 is a schematic graph illustrating the dependency of a growth temperature and a PL emission intensity on a molar ratio of supplied In when an InₓGa₁₋ₓN layer with the same emission wavelength is formed by c-plane growth.

FIG. 11 is a graph for illustration of the concept of the present disclosure. FIG. 11 schematically illustrates the dependency of a growth temperature and a PL emission intensity on a molar ratio of supplied In when an InₓGa₁₋ₓN layer with a same emission wavelength is grown by m-plane growth.

FIG. 12 is a graph for illustration of the concept of the present disclosure. FIG. 12 schematically illustrates the dependency of a growth temperature and a PL emission intensity on a molar ratio of supplied In and a V/III ratio when an InₓGa₁₋ₓN layer with a same emission wavelength is formed by m-plane growth together with a comparison example.

FIG. 13 is a schematic cross-sectional view illustrating the structure of a gallium nitride-based compound semiconductor light-emitting device for comparison between the comparison example and the present disclosure.

FIG. 14 is a graph illustrating the relation between internal quantum efficiency and measured PL temperature characteristics in the comparison example.

FIG. 15 is a micrograph for analyzing the In concentration distribution of a GaN-based semiconductor light-emitting device according to the comparison example using an atom probe microscope.

FIG. 16 is a micrograph for analyzing the In concentration distribution of a GaN-based semiconductor light-emitting device according to the present disclosure using an atom probe microscope.

FIG. 17 is a schematic cross-sectional view illustrating a GaN-based semiconductor light-emitting device according to a first embodiment.

FIGS. 18A and 18B are micrographs for analyzing the In concentration distribution of a GaN-based semiconductor light-emitting device according to the first embodiment using an atom probe microscope. FIG. 18A illustrates the cross-section having the horizontal axis along the a-axis direction. FIG. 18B illustrates the cross-section having the horizontal axis along the c-axis direction.

FIG. 19 is a graph illustrating the relation between internal quantum efficiency and measured PL temperature characteristics in the first embodiment.

FIG. 20 is a schematic cross-sectional view illustrating a GaN-based semiconductor light-emitting device (LED device) according to a second embodiment.

FIG. 21 is a graph illustrating the relation between external quantum efficiency and injected currents in the light-emitting device according to the second embodiment, which is indicated by black diamonds, and the light-emitting device according to the comparison example, which is indicated by white squares.

FIG. 22 is a graph illustrating the relation between operating voltages and injected currents in the light-emitting device according to the second embodiment, which is indicated by black diamonds, and the light-emitting device according to the comparison example, which is indicated by white squares.

FIGS. 23A and 23B illustrate a growth surface of a nitride semiconductor layer in a GaN-based semiconductor light-emitting device according to a variation of the second embodiment. FIG. 23A is a schematic perspective view illustrating the crystal structure (i.e., the wurtzite crystal structure) of the GaN-based semiconductor. FIG. 23B is a perspective view illustrating the relation among a normal line of the m-plane, a +c-axis direction, and an a-axis direction.

FIGS. 24A and 24B are schematic cross-sectional views illustrating the positional relation between a principal surface and the m-plane of a GaN-based compound semiconductor layer.

FIGS. 25A and 25B are schematic cross-sectional views illustrating the principal surface and the vicinity of the GaN-based compound semiconductor layer.

FIG. 26 is a schematic cross-sectional view illustrating a white light source apparatus according to a third embodiment.

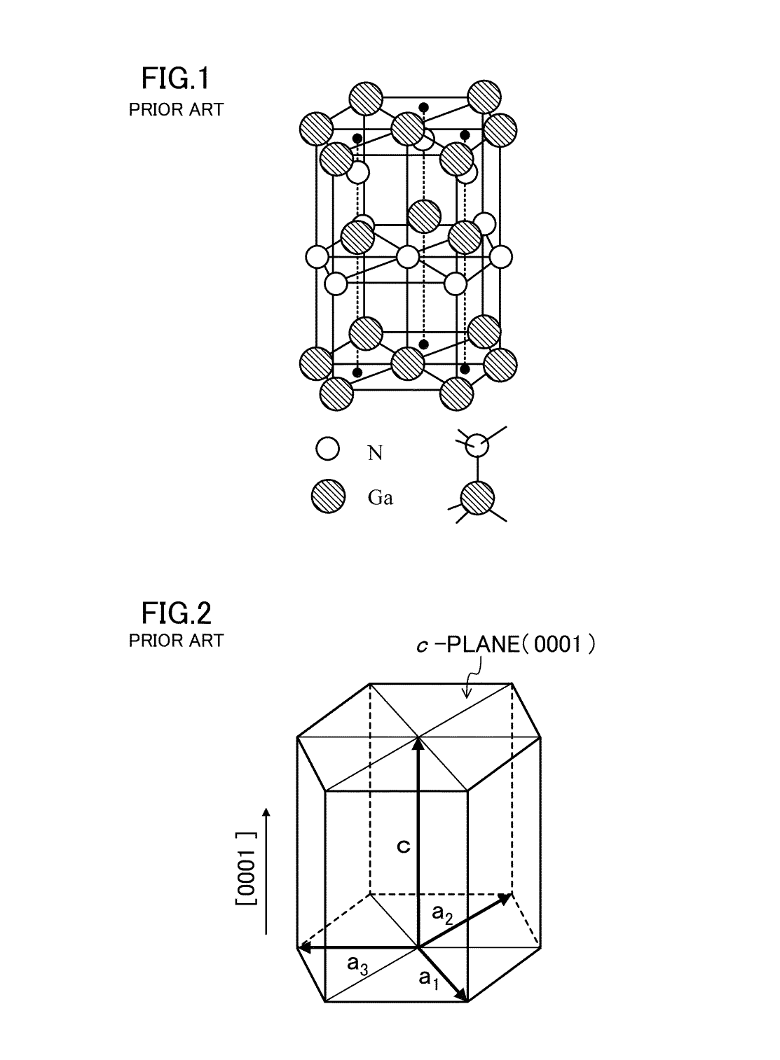

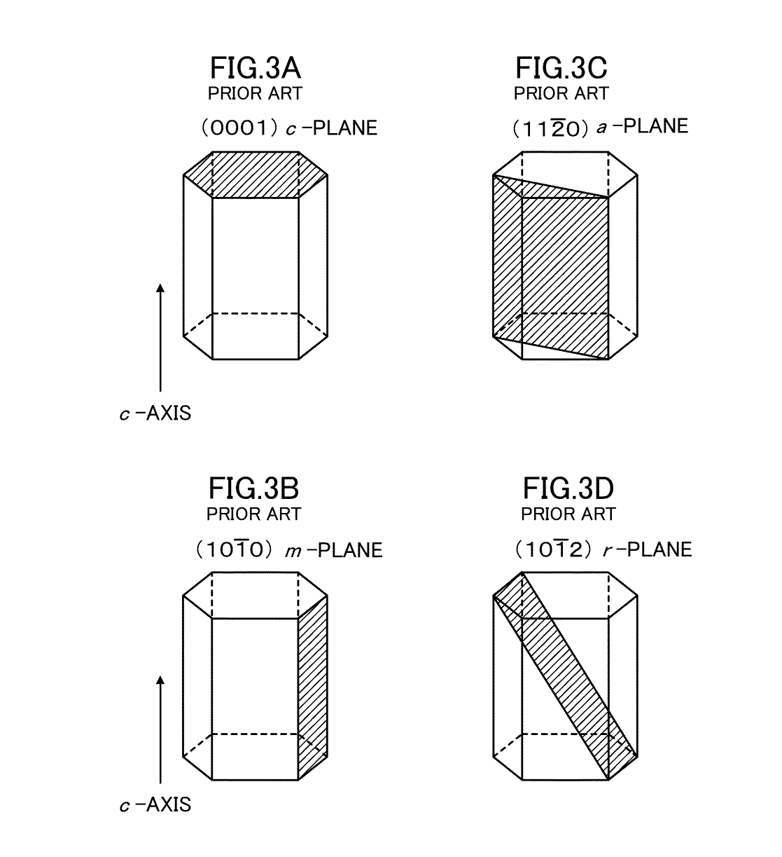

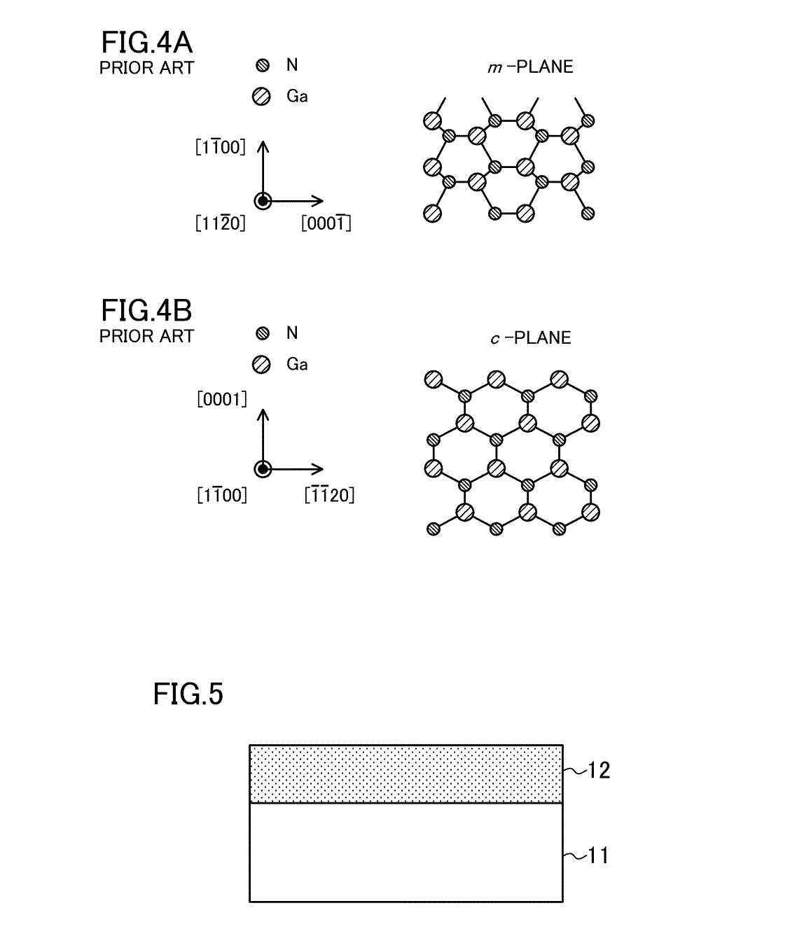

### DETAILED DESCRIPTION

A first aspect of the present disclosure provides a gallium nitride-based compound semiconductor light-emitting device formed of nitride semiconductor expressed by a general expression AlₓIn_{y}Ga_{z}N, where 0≦x<1, 0<y<1, 0<z<1, and x+y+z=1. The device includes a light-emitting layer having a growth surface of a non-polar plane or a semi-polar plane. A growth surface of the nitride semiconductor has two anisotropic axes. An In composition of the nitride semiconductor has distribution changing along a first axis of the two axes. An interface between a region with a low In composition and a region with a high In composition is inclined from a plane perpendicular to the first axis toward the growth surface.

In the first aspect, the In composition of the nitride semiconductor may be uniform along a second axis of the two axes.

In the first aspect, the region with the low In composition or the region with the high In composition may have a fine line structure extending along the second axis of the two axes in a cross-section parallel to the second axis.

A second aspect of the present disclosure provides a gallium nitride-based compound semiconductor light-emitting device formed of nitride semiconductor expressed by a general expression AlₓIn_{y}Ga_{z}N, where 0≦x<1, 0<y<1, 0<z<1, and x+y+z=1. The device includes a light-emitting layer having a growth surface of a non-polar plane or a semi-polar plane. A growth surface of the nitride semiconductor has two anisotropic axes. The nitride semiconductor includes a low In concentration region having an In concentration lower than an In concentration of a high In concentration region contributing to light emission. The low In concentration region is inclined along a first axis of the nitride semiconductor, and is in a band-like shape extending along a second axis.

In the first or the second aspect, the growth surface may have a plurality of steps along an m-plane.

In the first or the second aspect, the growth surface may be an m-plane. The first axis may be along an a-axis direction. The second axis may be along a c-axis direction.

In the first or the second aspect, the growth surface may be the semi-polar plane. The first axis is along one of the two axes, which has a component of a c-axis direction.

In the first or the second aspect, the growth surface may be a (11-22) plane. The first axis may be along a [-1-123] axis direction. The second axis may be along an m-axis direction.

In the first or the second aspect, the growth surface may be a (20-21) plane. The first axis may be along a [10-1-4] axis direction. The second axis may be along an a-axis direction.

In the first or the second aspect, the growth surface may be a (1-102) plane. The first axis may be along a [1-101] axis direction. The second axis may be along an a-axis direction.

In the first or the second aspect, the In composition of the region with the low In concentration region of the nitride semiconductor may be not higher than 80% of the In composition of the region with the high In composition.

In the first or the second aspect, the In composition of the region with the low In concentration of the nitride semiconductor may be not less than 50% and not more than 80% of the In composition of the region with the high In composition.

In the first or the second aspect, the light-emitting layer may be at least one quantum well layer.

In this case, the quantum well layer may have a thickness not less than 2 nm and not more than 20 nm.

In this case, the quantum well layer may have a thickness not less than 6 nm and not more than 16 nm.

In the first or the second aspect, the region with the low In composition may include a plurality of regions with the low In composition. The low In concentration region may include a plurality of low In concentration regions. A distance between a pair of the regions with the low In composition or between a pair of the low In concentration regions may be not less than 10 nm and not more than 100 nm. A width of the region with the low In composition or a width of the low In concentration region may be not less than 1 nm and not more than 20 nm.

According to yet another aspect, a light source apparatus may include the gallium nitride-based compound semiconductor light-emitting device of any one of the above-described aspects; and a wavelength converter including a fluorescent member converting a wavelength of light emitted from the gallium nitride-based compound semiconductor light-emitting device.

### History

As principal motivation for arriving at the present disclosure, the present inventors focused on the slip planes of a GaN/InGaN layer and a GaN/AlₓIn_{y}Ga_{z}N layer, where 0≦x<1, 0<y<1, 0<z<1, and x+y+z=1, which are formed by non-polar m-plane growth. The reason will be described below. For simplicity, the “InGaN layer” denotes an InGaN layer and an AlₓIn_{y}Ga_{z}N layer, where 0≦x<1, 0<y<1, 0<z<1, and x+y+z=1.

FIG. 5 illustrates the cross-sectional structure of an m-plane InGaN layer 12 with a thickness of 200 nm. The InGaN layer 12 has been grown on the principal surface of a GaN substrate 11 having a plane orientation of the m-plane (i.e., the (10-10) plane) beyond the critical thickness causing dislocation. The present inventors researched the relaxation phenomenon in the m-plane InGaN layer of this case.

Conventionally, the c-plane has been known as the slip plane causing dislocation in wurtzite gallium nitride (GaN). However, the present inventors discovered that a unique slip plane different from the c-plane occurs along the m-plane.

The present inventors measured the m-plane InGaN layer 12 with the thickness beyond the critical thickness by reciprocal lattice mapping of symmetric reflection. The mapping was performed using an X-ray diffractometer by irradiating the layer with the X ray in the c-axis direction and the a-axis direction, which are the anisotropy directions in the growth surface.

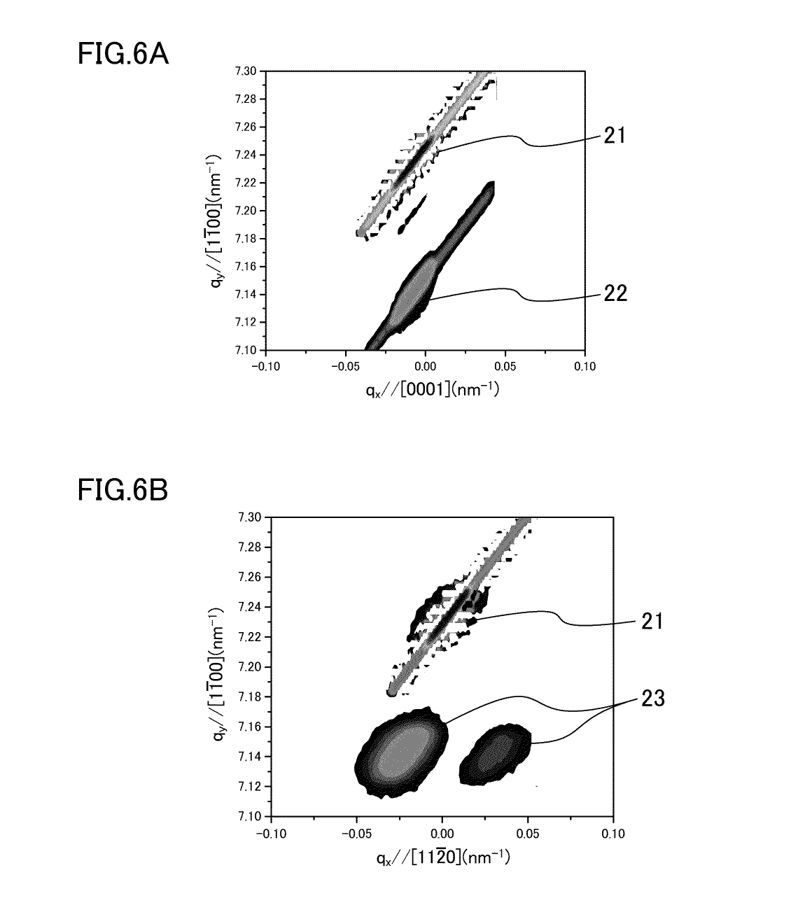

FIGS. 6A and 6B illustrate an obtained result of the reciprocal lattice mapping of the symmetric reflection. FIG. 6A illustrates the result where the X ray is incident along the c-axis (i.e., the [0001] direction). As clear from FIG. 6A, a diffraction peak 21 of the substrate 11 is similar to a diffraction peak 22 of the InGaN layer 12 in a q_{X-}coordinate represented by the horizontal axis. This shows that the m-plane InGaN layer 12 is grown coherently in the c-axis direction.

FIG. 6B illustrates the result where the X ray is incident along the a-axis (i.e., [11-20] direction). As clear from FIG. 6B, the m-plane InGaN layer 12 is divided into two portions, and diffraction peaks 23 of the divided portions are not similar to the diffraction peak 21 of the substrate 11 in the q_{X-}coordinate represented by the horizontal axis. Generally in reciprocal lattice mapping of symmetric reflection, the phenomenon of dissimilarity between the diffraction peak of a substrate and the diffraction peak of a thin film in a q_{X-}coordinate of the horizontal axis indicates that the principal axis direction of the thin film is inclined with respect to the principal axis direction of the substrate.

From the foregoing, the present inventors discovered that the m-plane InGaN layer 12 was formed on the substrate 11 with the lattice inclined in the a-axis direction. They also discovered that the tilt direction was symmetrically divided along two directions in the a-axis direction. This indicates that the lattice is inclined along the two symmetrical directions in the a-axis direction.

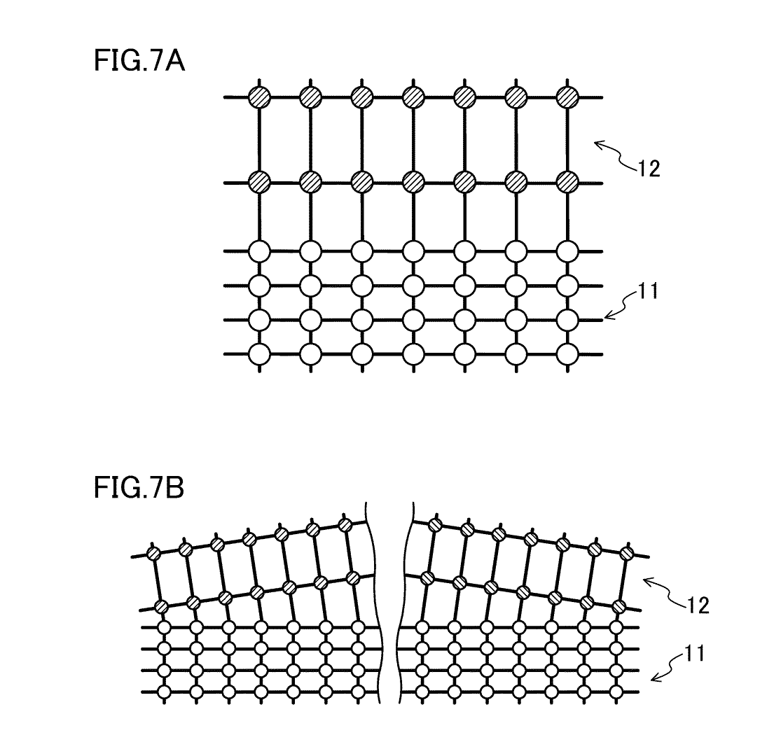

FIG. 7A schematically illustrates the lattice match between the substrate 11 and the m-plane InGaN layer 12 in the c-axis direction. FIG. 7B schematically illustrates the lattice tilt of the m-plane InGaN layer 12 from the substrate 11 in the a-axis direction. This study clarified that the lattice relaxation phenomenon of the m-plane InGaN layer 12 has in-plane anisotropy against the substrate 11 formed of the m-plane GaN along the non-polar m-plane.

To understand the phenomenon, the present inventors also studied as follows.

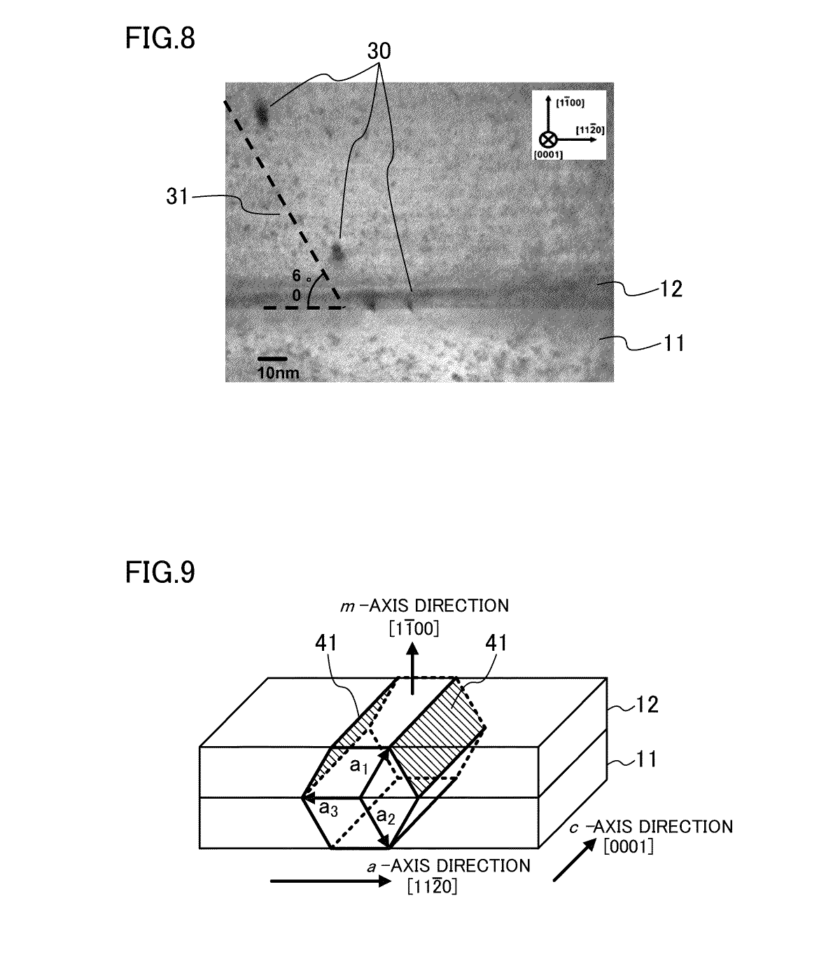

FIG. 8 illustrates a result of transmission electron microscopy (TEM) observing the cross-section parallel to the c-plane of an InGaN layer grown beyond the critical thickness. By the TEM, the present inventors observed the obtained lattice tilt when an X ray was incident in the a-axis direction.

FIG. 8 shows that dislocation 30 caused by the lattice mismatch at the interface between the substrate 11 and the m-plane InGaN layer 12. In addition, it is found that the angle between the interface and the plane along which the dislocation 30 is formed in an oblique direction (i.e., a dislocation formation plane 31) is about 60°. The dislocation formation plane 31 is considered as a slip plane. An error of measurement in the angle between the interface and the dislocation formation plane 31 is about ±5°. Conventionally, the c-plane has been known as the slip plane of wurtzite gallium nitride caused by dislocation. However, FIG. 8 shows that the slip plane of the m-plane InGaN layer 12 is not the c-plane but the m-plane. That is, the slip plane is the m-plane inclined in the growth surface direction from the plane perpendicular to the a-axis in the growth surface of the m-plane InGaN layer 12.

FIG. 9 is a schematic perspective view illustrating in-plane anisotropy and the slip plane of an InGaN layer grown beyond the critical thickness. In GaN-based semiconductor grown on the m-plane, a slip plane 41 occurs in an m-plane different from the growth surface. The two m-planes being slip planes 41 are symmetrically spaced apart from one another with respect to the perpendicular line (i.e., a normal line) of the principal surface. This accords with the phenomenon shown in FIG. 6B that the diffraction peaks 23 of the m-plane InGaN layer 12 are symmetrically divided. This clarified the relaxation phenomenon, i.e., the lattice tilt, unique to the m-plane InGaN layer 12.

The present inventors studied the relation between the m-plane as the slip plane, and non-luminescent centers of oxygen impurities, etc.

The non-polar plane or the semi-polar plane may be largely influenced by the non-luminescent centers caused by the oxygen impurities, which may be incorporated into an InGaN lattice site. In general, nitrogen tends to lack in nitride semiconductor, thereby generating holes in the nitrogen sites. When oxygen impurity atoms substitute the nitrogen sites (group V sites) being the holes, a Ga—O bond occurs. However, the dissociation energy of the Ga—O bond is 3.90 eV, and the dissociation energy of an O—O bond is 5.10 eV. The Ga—O bond relatively tends to dissociate. Thus, a cluster of oxygen impurity atoms such as an O—O bond tends to be formed. Specifically, the oxygen impurity atoms move between lattice sites among the lattice atoms to form the O—O bond. As a result, the oxygen impurity atoms become stable as an oxygen impurity atoms cluster or a chain of the oxygen impurity atoms. At this time, the oxygen impurity atoms incorporated into the InGaN layer move in the lattice to substitute the other oxygen impurities existing in the N sites due to the Ga—O bond with relatively low dissociation energy.

This tendency of the atom movement in the lattice significantly well corresponds to the characteristics of the slip plane at which the lattice tends to move. Specifically, the oxygen impurity atoms are considered to have tendency of interlattice movement along the slip plane. Therefore, the non-luminescent centers caused by the chain of the oxygen impurities is considered to concentrate along the slip plane.

As described above, since the slip plane is the m-plane inclined in the a-axis direction from the growth surface of the m-plane InGaN layer 12, the non-luminescent centers of the oxygen impurities tend to be formed on the m-plane inclined in the a-axis direction, thereby reducing luminous efficiency.

After repetitive hard study focused on incorporating oxygen into a light-emitting layer (i.e., an active layer), the present inventors discovered how to reduce the influence of the non-luminescent centers formed obliquely at the slip plane of the m-plane grown GaN/InGaN multiple quantum well active layer. That is, the present inventors discovered that the vicinity of the slip plane is formed as a low In composition region, i.e., a low In concentration region to serve as an energy barrier for the carriers, thereby largely improving the luminous efficiency in the light-emitting device.

### —Supply Ratio of Group V Material Gas to Group III Material Gas (V/III Ratio)—

A manufacturing method of the gallium nitride-based compound semiconductor light-emitting device according to the present disclosure includes forming a GaN-based semiconductor layer having a principal surface of a non-polar plane (e.g., the m-plane or the a-plane) or a semi-polar plane (e.g., the r-plane, the (11-22) plane, or the (20-21) plane), by metal-organic chemical vapor deposition (MOCVD).

In the present disclosure, the parameters defining the growth condition in the MOCVD are adjusted to form a GaN-based semiconductor layer emitting light with a desired wavelength. The parameters defining the growth condition include pressure, the growth rate, the growth temperature, and the molar ratio of In material gas supply (i.e., the molar ratio of In supply) contained in Group III material gas.

In the present disclosure, material gas is supplied to the reaction chamber of an MOCVD apparatus to perform crystal growth of an indium gallium nitride (InₓGa₁₋ₓN, where 0<x<1)) layer having a principal surface being a plane, which has a slip plane having a plane orientation different from the c-plane. A representative specific example of the plane, which has a slip plane having a plane orientation different from the c-plane, is the above-described non-polar m-plane. On the other hand, in a nitride semiconductor layer having a principal surface of the r-plane, the (11-22) plane, or the (20-21) plane being a semi-polar plane, the slip plane is the c-plane.

For simplicity, the m-plane growth being growth on a non-polar plane will be described below. The present disclosure is not limited to the m-plane growth, and widely applicable to formation of an InₓGa₁₋ₓN layer having a crystal plane different from the principal surface which is the growth surface of the nitride semiconductor layer. In the crystal growth of the InₓGa₁₋ₓN layer, a material gas containing indium (In), a material gas containing gallium (Ga), and a material gas containing nitrogen (N) are supplied to the reaction chamber at the same time. The gas containing In and the gas containing Ga are group III material gas. On the other hand, the material gas containing N is group V material gas. In order to obtain a desired emission wavelength, there is a need to adjust the In composition x in the InₓGa₁₋ₓN layer to be a desired value. Thus, in the present disclosure, the values of the growth temperature, the molar ratio of In supply, and the V/III ratio are adjusted in the crystal growth in addition to the predetermined parameters such as the pressure and the growth rate.

Specifically, the molar ratio of In supply is determined based on the molar flow rate (mol/min) of the material gas of Ga and In being group III atoms supplied to the reaction chamber for one minute in the growth of the InₓGa₁₋ₓN layer. In the present disclosure, the “molar ratio of In supply” represents the ratio of the molar flow rate of the supplied In material gas to the total molar flow rate of the In material gas and the Ga material gas supplied to the reaction chamber. Thus, the molar ratio of In supply is expressed by the following equation (1):

Molar Ratio of Supplied In=[Supplied In Material Gas]/([Supplied In Material Gas]+[Supplied Ga Material Gas]) (1)

where the molar flow rate (mol/min) of the supplied Ga material gas for one minute is [supplied Ga material gas], and the molar flow rate (mol/min) of the supplied In material gas for one minute is [supplied In material gas].

The In material gas is, for example, trimethylindium (TMI). The [supplied In material gas] is also referred to as [TMI]. The Ga material gas is, for example, trimethylgallium (TMG) or triethylgallium (TEG). The [supplied Ga material gas] is also referred to as [TMG] or [TEG]. [TMI] represents the molar flow rate (mol/min) of supplied TMI for one minute. Similarly, [TMG] represents the molar flow rate (mol/min) of supplied TMG for one minute, and [TEG] represents the molar flow rate (mol/min) of supplied TEG for one minute.

In the present disclosure, the [supplied In material gas] is referred to as [TMI], and the [supplied Ga material gas] is referred to as [TMG] for simplicity. The molar ratio of In supply is expressed by the following equation (2).

Molar ratio of Supplied In=[TMI]/([TMI]+[TMG]) (2)

It is usually difficult to actually measure the supply amount and the partial pressure of In contributing the actual reaction in growing an InₓGa₁₋ₓN layer by MOCVD. Thus, in the present disclosure, the molar flow rate of the material gas supplied to the reaction chamber is selected as one of control factors of the intake rate of In. That is, the pressure, the growth temperature, the molar ratio of In supply, or the growth rate may be selected as the control factor of the In composition x of the InₓGa₁₋ₓN layer.

As indicated by the equation (2), the molar ratio of In supply is expressed by [TMI] and [TMG]. On the other hand, the growth rate is substantially determined by [TMG].

In the present disclosure, the V/III ratio represents the ratio of the molar flow rate of the supplied ammonia (NH₃) gas, which is the group V material, to the total molar flow rate of the In material gas and the Ga material gas supplied to the reaction chamber. Thus, the V/III ratio is expressed by the equation (3):

V/III Ratio=[Supplied NH₃ Material Gas]/([Supplied In Material Gas]+[Supplied Ga Material Gas]) (3)

where the molar flow rate (mol/min) of the supplied NH₃ material gas for one minute is [supplied NH₃ material gas].
In the present disclosure, the V/III ratio is expressed by the following equation (4):

V/III Ratio=[NH₃]/([TMI]+[TMG]) (4)

where the NH₃ supply flow rate is expressed by [NH₃] for simplicity.

It is usually difficult to actually measure an effective value such as the V/III ratio contributing the actual reaction in growing an InₓGa₁₋ₓN layer by MOCVD. Thus, in the present disclosure, the molar flow rate of the material gas supplied to the reaction chamber is selected as an example. However, since the reaction efficiency of the material is varied from a reactor to another, the same growth condition is established, even if the molar flow rate of the material gas supplied to the reaction chamber is different. That is, the manufacturing method of the gallium nitride-based compound semiconductor light-emitting device according to the present disclosure is not limited to the supply amount of the material gas or the V/III ratio, which will be described below. With use of a different MOCVD apparatus, the reaction efficiency of the material gas is different, and an advantage equivalent to that of the present disclosure can be obtained using the same growth condition caused by reaction even at a different supply ratio.

In the present disclosure, a plurality of In_{y}Ga_{1-y}N layers, where 0<y<1, each having a principal surface of a non-polar plane or a semi-polar plane, are formed under different growth conditions. The relation between the growth temperature and the molar ratio of In supply is obtained where the pressure and the growth rate are constant under the growth condition for forming InₓGa₁₋ₓN layers, where 0<x<1, with the equal emission wavelength, out of the plurality of In_{y}Ga_{1-y}N layers, where 0<y<1. The relation between the growth temperature and the molar ratio of In supply where the pressure and the growth rate are constant is suitably expressed by a curved line (including a polygonal line) in a graph. In the graph, the vertical axis represents the growth temperature, and the horizontal axis represents the molar ratio of In supply. In the present disclosure, such a curved line is referred to as a “characteristic line.”

For deeper understanding of the present disclosure, conventional formation of an InₓGa₁₋ₓN layer, where 0<x<1, by c-plane growth will be described first.

In general, the In composition x of an InₓGa₁₋ₓN layer varies depending on both of the growth temperature and the molar ratio of In supply of the InₓGa₁₋ₓN layer. In other words, even if the molar ratio of In supply is the same, the In composition x of an InₓGa₁₋ₓN layer is different as long as the growth temperature is different. Even if the growth temperature is the same, the In composition x of the grown InₓGa₁₋ₓN layer is different as long as the molar ratio of In supply is different. Since the emission wavelength is determined by the In composition x, there is a need to determine both of the growth temperature and the molar ratio of In supply to obtain an InₓGa₁₋ₓN layer emitting light with a desired wavelength.

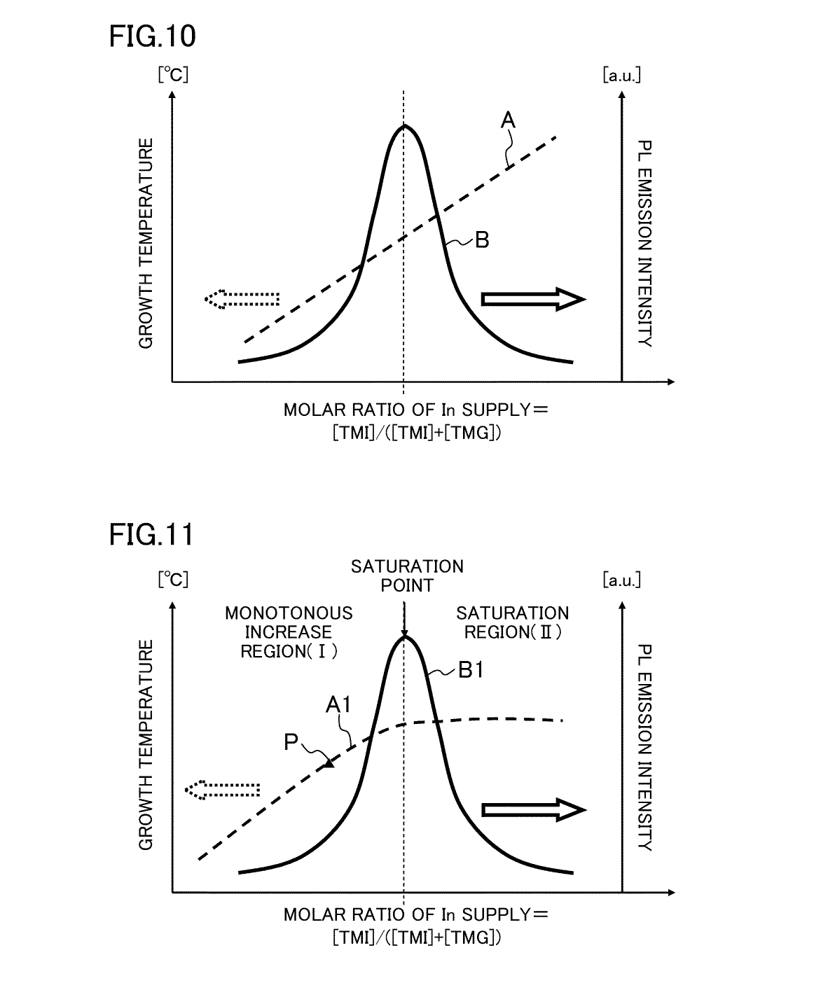

In the graph of FIG. 10, the straight line (i.e. the broken line) A represents the relation between the growth temperature and the molar ratio of In supply needed for the c-plane growth of the InₓGa₁₋ₓN layer with a specific In composition ratio x (e.g., x=0.1). The vertical axis on the left of the graph represents the growth temperature (° C.). As clear from the straight line A, in growing the c-plane InₓGa₁₋ₓN layer with the specific In composition, when the molar ratio of In supply is increased, there is a need to raise the growth temperature. That is, there is a linear relation between the growth temperature and the molar ratio of In supply.

As described above, the straight line A represents an example relation between the growth temperature and the molar ratio of In supply, both of which are required for the c-plane growth of an In_{0.1}Ga_{0.9}N layer. Thus, the In_{0.1}Ga_{0.9}N layer is obtained by the c-plane growth of the InₓGa₁₋ₓN layer at the growth temperature and at the molar ratio of In supply determined by a position in the straight line A shown in FIG. 10. By changing the growth temperature and the molar ratio of In supply along the straight line A, an In_{0.1}Ga_{0.9}N layer with the same composition (i.e., the same emission wavelength) can be formed under the different growth conditions. That is, the In composition x of the obtained InₓGa₁₋ₓN layers is constant without depending on the position in the straight line.

On the other hand, the curved line B shown in FIG. 10 illustrates the relation between the molar ratio of In supply and photoluminescence (PL) emission intensity. In the graph on the right, the vertical axis represents the PL emission intensity (at an arbitrary unit). The curved line B of FIG. 10 shows that the PL emission intensity obtained from an InₓGa₁₋ₓN layer (e.g., an In_{0.1}Ga_{0.9}N layer) varies depending on the position in the straight line A. That is, it is found that the PL emission intensity has a maximum value (i.e., a peak value) at a specific molar ratio of In supply.

A reason for the variation of the PL emission intensity depending on the molar ratio of In supply is that the crystallinity varies depending on the growth temperature and the molar ratio of In supply even with the same In composition x of the InₓGa₁₋ₓN layer. When the InₓGa₁₋ₓN layer has most excellent crystallinity, the PL emission intensity has the maximum value.

The present inventors confirmed that, unlike conventional c-plane growth, two regions exist in forming a GaN-based semiconductor layer having a principal surface of a non-polar plane or a semi-polar plane by MOCVD (see FIG. 11). In one region, the growth temperature monotonously increases with an increase in the molar ratio of In supply (i.e., a monotonous increase region). In the other region, the temperature is saturated (i.e., a saturation region). In the curved characteristic line, a saturation point exists at the boundary between the monotonous increase region and the saturation region. In addition, the present inventors discovered that an InₓGa₁₋ₓN layer with excellent crystallinity is obtained and the emission intensity of a device can be increased by growing the InₓGa₁₋ₓN layer having a principal surface of a non-polar plane or a semi-polar plane under the growth condition corresponding to the saturation point.

FIG. 11 is a graph schematically illustrating an example condition for forming an m-plane InₓGa₁₋ₓN layer according to the present disclosure. FIG. 11 corresponds to FIG. 10. In the graph, the curved line (i.e. the broken line) A1 is a curved characteristic line representing the relation between the molar ratio of In supply and the growth temperature for forming the m-plane InₓGa₁₋ₓN layer with the same emission wavelength. The curved line A1 represents an example relation between the molar ratio of In supply and the growth temperature, which are required for forming an InₓGa₁₋ₓN layer, where x=0.1, with an emission wavelength having a peak of about 410 nm. The molar ratio of In supply corresponding to the point P in the curved line A1 is, for example, 0.5. The growth temperature corresponding to the point P is about 770° C. If the molar ratio of In supply corresponding to the point P is used, and the growth temperature deviates from the growth temperature corresponding to the point P, a desired InₓGa₁₋ₓN layer, where x=0.1, cannot be formed, and the In composition ratio x varies from 0.1.

In order to obtain a desired In composition x, two control factors for the molar ratio of In supply and the growth temperature need to satisfy the relation expressed by the curved characteristic line A1. The curved characteristic line A1 changes even under different growth pressure. It also changes even if a desired In composition x is different. The form of the curved characteristic line A1 is determined by giving growth pressure and a desired In composition x.

According to the experiment by the present inventors, in the range of a relatively low molar ratio of In supply, the growth temperature monotonously increases with an increase in the molar ratio of In supply. In the range of a relatively high molar ratio of In supply, the growth temperature is almost constant without depending on the molar ratio of In supply. The former is referred to as a “monotonous increase region (I),” and the latter is referred to as a “saturation region (II).” The saturation point exists at the boundary between the monotonous increase region (I) and the saturation region (II). Such a form of the curved characteristic line A1 is largely different from the form of the curved characteristic line in the c-plane growth.

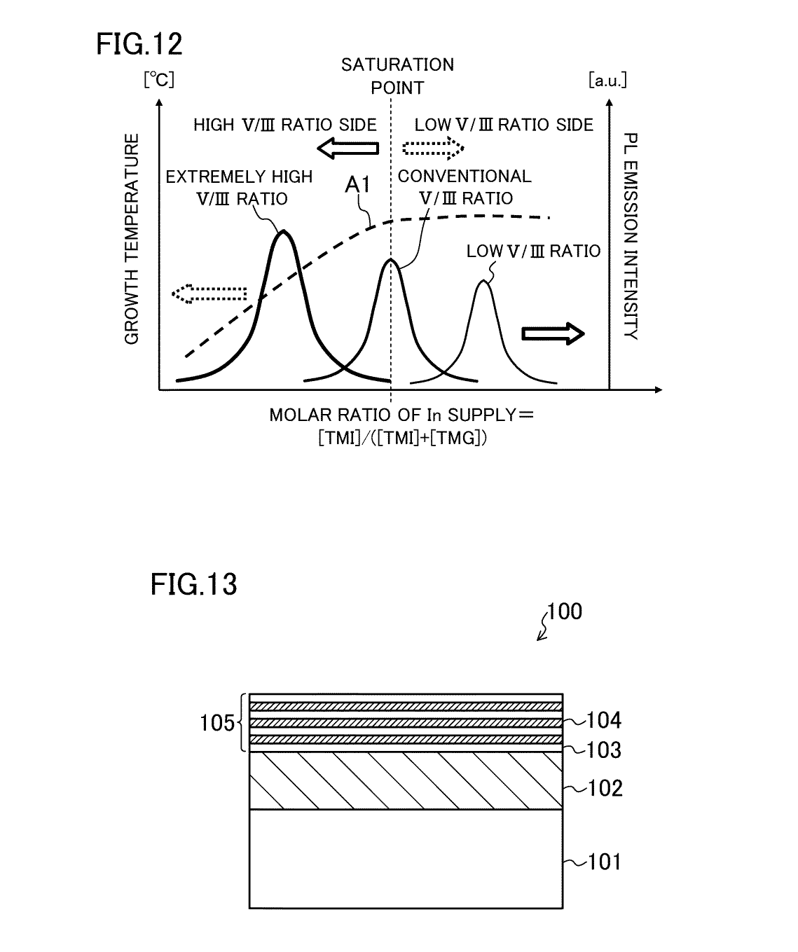

As shown in FIG. 12, the present inventors discovered from an experiment that the peak of the PL emission intensity changes by the study of changing the V/III ratio in the curved characteristic line A1.

Specifically, the V/III ratio most suitable for forming an InₓGa₁₋ₓN layer conventionally ranges from about 3000 to about 6000. At this conventional V/III ratio, the PL emission intensity is the maximum under the growth condition corresponding to the saturation point in the curved characteristic line A1.

Instead of the suitable V/III ratio for forming, for example, a conventional InₓGa₁₋ₓN layer, the present inventors studied using a low V/III ratio ranging from about 500 to about 2000. In this case, the PL emission intensity was not the maximum under the growth condition corresponding to the saturation point in the curved characteristic line A1. It was the maximum in the region with a high molar ratio of In supply, i.e., in the saturation region (II).

Instead of the suitable V/III ratio for forming, for example, a conventional InₓGa₁₋ₓN layer, the present inventors studied using a significantly high V/III ratio ranging from about 10000 to about 30000. In this case, the PL emission intensity was not the maximum under the growth condition corresponding to the saturation point in the curved characteristic line A1. It was the maximum in the region with a low molar ratio of In supply, i.e., in the monotonous increase region (I).

The present inventors compared the maximum values of the PL emission intensity at the various V/III ratios, and as a result, discovered that the maximum value of the PL emission intensity improves with an increase in the V/III ratio and with a decrease in the molar ratio of In supply.

Attention needs to be paid on the fact that the relation between the molar ratio of In supply and the growth temperature, which correspond to the saturation point in the curved characteristic line A1, hardly changes even with a change in the V/III ratio in the material gas. That is, by finding the molar ratio of In supply and the growth temperature, which correspond to the saturation point in the curved characteristic line A1, the growth condition for the maximum PL emission intensity at a significantly high V/III ratio can be determined in the monotonous increase region (I).

Next, the present inventors will describe that the significantly high V/III ratio in the present disclosure is a growth condition in the region which cannot be implemented in conventional c-plane growth.

Conventionally, in performing c-plane growth of an InₓGa₁₋ₓN layer, where 0<x<1, by MOCVD, the crystal growth is usually performed at a temperature as high as possible to reduce degradation in the crystallinity and in the decomposition efficiency of NH₃. In this case, since the ratio of In desorbing from the crystal is increased by evaporation, and the In atoms hardly enter the inside of the crystal, there is a need to increase the flow rate of the supplied In as much as possible. As described above, the active layer (i.e., the light-emitting layer) preferably has a thickness of 3.0 nm or less due to the Stark effect of the polar plane. Thus, the growth rate of the active layer need to be about 4.0 nm/min or lower. Since the In composition x is small in a visible light region, the growth rate of the active layer formed of InₓGa₁₋ₓN is determined by the supply amount of the Ga atoms. Therefore, the growth rate of the InₓGa₁₋ₓN layer is expressed by the function of [TMG].

In growth of a c-plane InₓGa₁₋ₓN layer, the amount of [TMI] is as great as possible, while the amount of [TMG] is small to reduce the growth rate. Thus, the molar ratio of In supply=[TMI]/([TMI]+[TMG]) is not less than about 0.90.

On the other hand, the growth of the m-plane InₓGa₁₋ₓN layer according to the present disclosure has lower intake efficiency of In than the c-plane growth. Thus, in order to increase the In composition x, a further increase in the molar ratio of In supply=[TMI]/([TMI]+[TMG]) is considered. However, as described above, the molar ratio of In supply is already about 0.90. There is no room for change and no advantage is expected. As such, in the m-plane growth, it is significantly difficult to provide an InₓGa₁₋ₓN layer emitting light at a long wavelength side with high In composition.

However, in the m-plane growth, as described above, since no Stark effect occurs, the thickness of the active layer can be greater than 3 nm to about 20 nm. Thus, the growth rate is increased to 4.5 nm/min or higher to enable crystal growth at much higher growth rate than the c-plane growth. In the experiment, the present inventors confirmed that the intake efficiency of In increases with an increase in the growth rate in the m-plane growth. Therefore, in the m-plane growth, when the amount of [TMG] is increased to improve the intake efficiency of In, the molar ratio of In supply=[TMI]/([TMI]+[TMG]) is smaller than in the c-plane growth.

As such, in the m-plane growth, an InₓGa₁₋ₓN layer can be grown at a higher growth rate than in the c-plane growth. In addition, the intake efficiency of In depends on [TMG] and [TMI] more greatly in the m-plane growth than in the c-plane growth. Thus, the intake efficiency of In in the m-plane growth can be controlled not only by the control factor such as the growth temperature but also by the molar ratio of In supply=[TMI]/([TMI]+[TMG]). This is not limited to the m-plane growth being non-polar plane growth, but is also applicable to the r-plane growth, the (11-22) plane growth, and (2-201) plane growth being semi-polar plane growth.

Specifically, under the growth condition according to the present disclosure, the molar ratio of In supply=[TMI]/([TMI]+[TMG]) need to be too small to be feasible in the c-plane growth. The growth condition also requires a significantly high V/III ratio of, for example, from three times to ten times the V/III ratio, which has been conventionally considered suitable for forming an InₓGa₁₋ₓN layer and sufficiently high. Therefore, the concept of the present disclosure cannot be easily anticipated.

### —Comparison Between Light-Emitting Layer Under Conventional Growth Condition in M-Plane Growth and Light-Emitting Layer of Present Disclosure—

Then, the present inventors observed and compared the structure of a light-emitting layer for comparison, which is formed of InₓGa₁₋ₓN at a conventional V/III ratio, and the structure of a light-emitting layer according to the present disclosure, which is formed of InₓGa₁₋ₓN at a significantly high V/III ratio using an atom probe microscope.

FIG. 13 schematically illustrates the cross-sectional structure of each sample (e.g., light-emitting device 100) used for analyzing the difference between the m-plane growth according to the conventional art and the m-plane growth according to the present disclosure. Electrodes for injecting currents to the light-emitting device 100 are not shown in this figure. First, a substrate 101 forming the light-emitting device 100 has a principal surface having plane orientation of a (10-10) m-plane. Gallium nitride (GaN) can be grown on a substrate. As the substrate 101, a free-standing substrate formed of GaN and having the m-plane as a principal surface is most preferable. Instead of the free-standing GaN substrate, it may be a 4H- or 6H-silicon carbide (SiC) having a lattice constant close to that of GaN, and exposing the m-plane. It may be a sapphire substrate exposing the m-plane. If the substrate 101 is formed of a material different from GaN-based semiconductor, a proper intermediate layer or a proper buffer layer is provided between the principal surface and the GaN-based semiconductor layer.

An underlying layer 102 formed of undoped GaN with a thickness ranging from about 1.0 μm to about 2.0 μm is formed on the principal surface of the substrate 101. A light-emitting layer 105 is formed on the underlying layer 102. The light-emitting layer 105 has a multiple quantum well (MQW) structure formed by alternately stacking barrier layers 103, each formed of undoped GaN with a thickness of about 30 nm, and well layers (i.e., active layers) 104, each formed of In_{0.09}Ga_{0.91}N with a thickness of about 15 nm. In the light-emitting device 100 used in this experiment, the light-emitting layer 105 includes three pairs of four barrier layers 103 and three active layers 104.

The well layers (i.e., the active layers) 104 formed of In_{0.09}Ga_{0.91}N generally have a thickness ranging from about 2.0 nm to about 20 nm, if the principal surface is a non-polar plane or a semi-polar plane. The more preferable thickness of the well layers 104 ranges from about 6.0 nm to about 16 nm. While the well layers 104, each having a thickness of about 15 nm, are used in the experiment, the well layers to be used may have any thickness within the range from about 2.0 nm to about 20 nm. The thickness of the barrier layers 103 is about 1.0-3.0 times greater than the thickness of the well layers 104. While the barrier layers 103, each having a thickness of 30 nm, are used in this experiment, similar advantages can be provided even if the barrier layers 103 have a different thickness.

Then, a manufacturing method of the light-emitting device 100 will be described.

The light-emitting device 100 is fabricated by MOCVD at growth pressure in the reaction chamber set to, for example, 300 Torr, where 1 Torr≈133.3 Pa. The carrier gas is hydrogen (H₂) gas and nitrogen (N₂) gas. The group III material gas is trimethylgallium (TMG) gas, or triethylgallium (TEG) gas and trimethylindium (TMI) gas. The group V material gas is ammonia (NH₃) gas.

First, the substrate 101 is cleaned with buffered hydrogen fluoride (BHF), then, sufficiently washed with water, and dried. After the cleaning, the substrate 101 is put into the reaction chamber of an MOCVD apparatus without being exposed to the air as much as possible. After that, the substrate 101 is heated to a temperature 850° C. while ammonia (NH₃) gas being the nitrogen source, and hydrogen (H₂) gas and nitride (N₂) gas being carrier gas are supplied to the reaction chamber to clean the surface of the substrate 101.

Then, for example, TMG gas is supplied to the reaction chamber, and the substrate 101 is heated at 1100° C. to grow the underlying layer 102 formed of GaN on the substrate 101. The underlying layer 102 is grown at a growth rate ranging from about 10 nm/min to about 40 nm/min.

Next, the TMG gas being the group III material gas is stopped. As the carrier gas, the hydrogen gas is stopped and only the nitrogen gas is supplied. In addition, the substrate temperature is reduced to the range from about 700° C. to about 800° C. to grow one of the barrier layers 103 formed of GaN on the underlying layer 102.

After that, the supply of the TMI gas is started to deposit one of the well layers 104 formed of InₓGa₁₋ₓN on the barrier layer 103. Three or more pairs of the barrier layers 103 and the well layers 104 are grown, thereby forming the light-emitting layer 105, which functions as a light-emitting portion and has a multiple quantum well structure formed of GaN/InGaN. The reason for stacking three or more pairs is that a larger number of the well layers 104 increases a volume capable of capturing the carriers contributing radiative recombination, thereby improving the luminous efficiency of the light-emitting device 100.

Next, how to measure the growth temperature in this experiment will be described.

A carbon susceptor is provided in the reaction chamber of an MOCVD apparatus. The substrate 101 is mounted directly on the carbon susceptor. A thermocouple measuring the growth temperature is located directly under the carbon susceptor surrounded by an electrical heater. The growth temperature according to the present disclosure is the temperature measured by the thermocouple.

First, the device structure shown in FIG. 13 is fabricated under a growth condition near the saturation point shown in FIG. 12 by using the conventional V/III ratio conventionally used as a most suitable condition. A specific condition follows. The pressure is 500 Torr, where 1 Torr≈133.3 Pa. The molar ratio of In supply obtained at a growth rate of about 6.0 nm/min is 0.5. The growth temperature is 755° C., and the V/III ratio is 5500. As a result, the m-plane In_{0.09}Ga_{0.91}N the well layers 104 with a PL emission wavelength of 405 nm are formed.

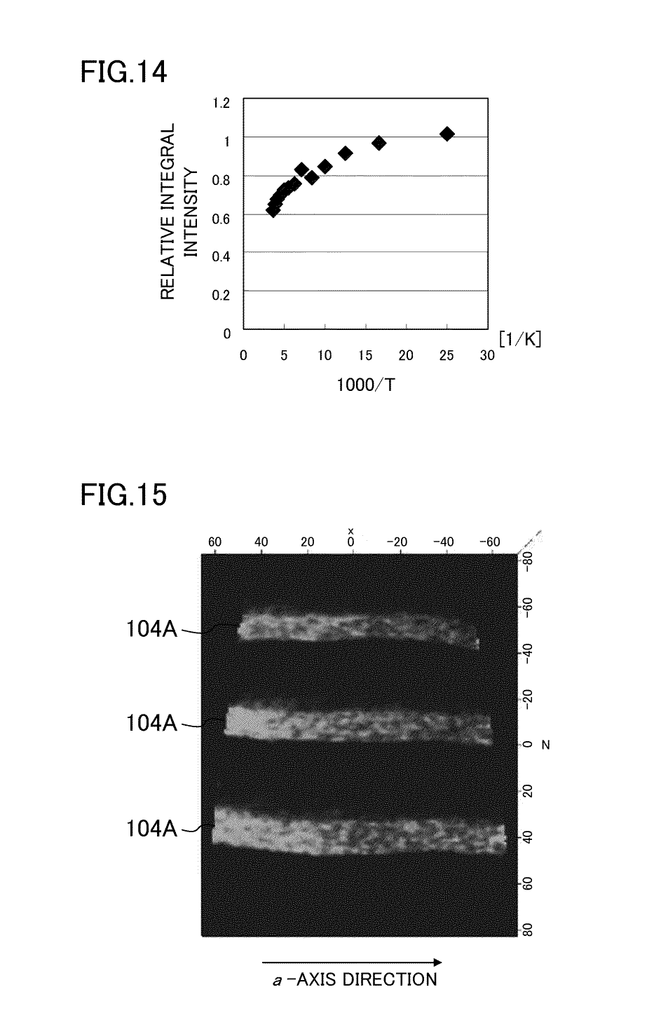

FIG. 14 illustrates a result of calculating the internal quantum efficiency of the light-emitting layer for comparison, which has been obtained under the conventional condition. The internal quantum efficiency is obtained by measuring the temperature characteristics ranging from 10 K to 300 K by PL. It is found from FIG. 14 that the internal quantum efficiency is about 66%.

FIG. 15 illustrates the result of observing the composition distribution of In in the light-emitting layer for comparison using an atom probe microscope. In FIG. 15, the horizontal axis is identical with the a-axis, and the cross-section parallel to the c-plane is observed. In FIG. 15, well layers of the light-emitting layer for comparison are denoted by the reference character 104A. The relatively white region with great contrast corresponds to a high In composition (i.e., high In concentration) region. The relatively dark ash region corresponds to a low In composition (i.e., low In concentration) region. As such, it is found through the atom probe microscope that the distribution of the In concentration is unstable, and there is no clear boundary between different In concentration distributions in the comparison example. Specifically, the In concentration distribution of the light-emitting layer for comparison gradually varies in the a-axis direction, and the In concentration distribution region contributing to light emission expands for about tens of nm.

As described above, the m-plane tends to absorb numbers of oxygen impurities, etc., which serves as the non-luminescent centers. In GaN-based semiconductor formed by the m-plane growth, the slip plane is inclined in the a-axis direction, and thus, non-luminescent centers of point defects in oxygen impurities, etc., are influenced by the plane orientation of the slip plane. That is, in the light-emitting layer for comparison, which has been obtained under the growth condition at the conventionally used V/III ratio, the In concentration distribution region expanding for about tens of nm and contributing to light emission includes some non-luminescent centers of point defects of oxygen impurities on a plane inclined in the a-axis direction.

It is found from the foregoing that the internal quantum efficiency is about 66% due to the non-luminescent centers at the conventionally used V/III ratio, and the advantages of the m-plane exhibiting non-polar characteristics are not sufficiently provided.

By contrast, in the present disclosure, as will be shown in the following embodiments, the In composition is reduced in the non-luminescent center region inclined in the a-axis direction using the growth condition of a significantly high V/III ratio in the material gas to reduce the influence of the non-luminescent centers of point defects of oxygen impurities inclined from the m-plane in the a-axis direction. This provides an energy barrier (i.e., potential barrier) for reducing traps to the non-luminescent centers of the carriers, thereby dramatically improving the internal quantum efficiency.

As described above, the present inventors discovered that, in GaN-based semiconductor formed by the non-polar plane or the semi-polar plane growth and having a slip plane inclined from the principal surface, the non-luminescent centers of the point defects in the impurities formed of oxygen, etc. in a light-emitting layer are obliquely inclined. In order to reduce the influence, the present inventors discovered selectively reducing the In composition the oblique non-luminescent center region. As a result, the influence of the non-luminescent centers can be reduced by the energy barrier.

The manufacturing method of the GaN-based semiconductor according to the present disclosure is not limited to the MOCVD apparatus used by the present inventors. Other apparatuses suitably implement the present disclosure.

In implementing the manufacturing method of the present disclosure, how to heat the substrate and how to measure the substrate temperature are not limited to what has been described above.

While in the present disclosure, the InₓGa₁₋ₓN layers, where 0<x<1, are the well layers of the light-emitting layer, the composition may contain aluminum (Al) depending on the use. Specifically, Al_{q}InᵣGaₛN layers, where 0≦q<1, 0<r<1, 0<s<1, and q+r+s=1, may be used instead of the InₓGa₁₋ₓN layers, where 0<x<1. The Al material gas may be trimethylaluminum (TMA) gas, or triethylaluminum (TEA) gas.

The manufacturing method of the GaN-based semiconductor according to the present disclosure is not limited to the MOCVD. Specifically, any crystal growth capable of suitably forming GaN-based semiconductor such as molecular beam epitaxy (MBE) and atomic layer epitaxy (ALE) may be used.

Where the MOCVD is not used, the growth condition of a significantly high V/III ratio in the above-described material gas cannot be used. It suffices if the feature of the present disclosure can be provided, i.e., if GaN-based semiconductor is formed by the non-polar plane or the semi-polar plane growth and has a slip plane inclined from the principal surface, and the In composition in the inclined non-luminescent center region is selectively reduced to reduce the influence of the non-luminescent centers using the energy barrier.

### First Embodiment

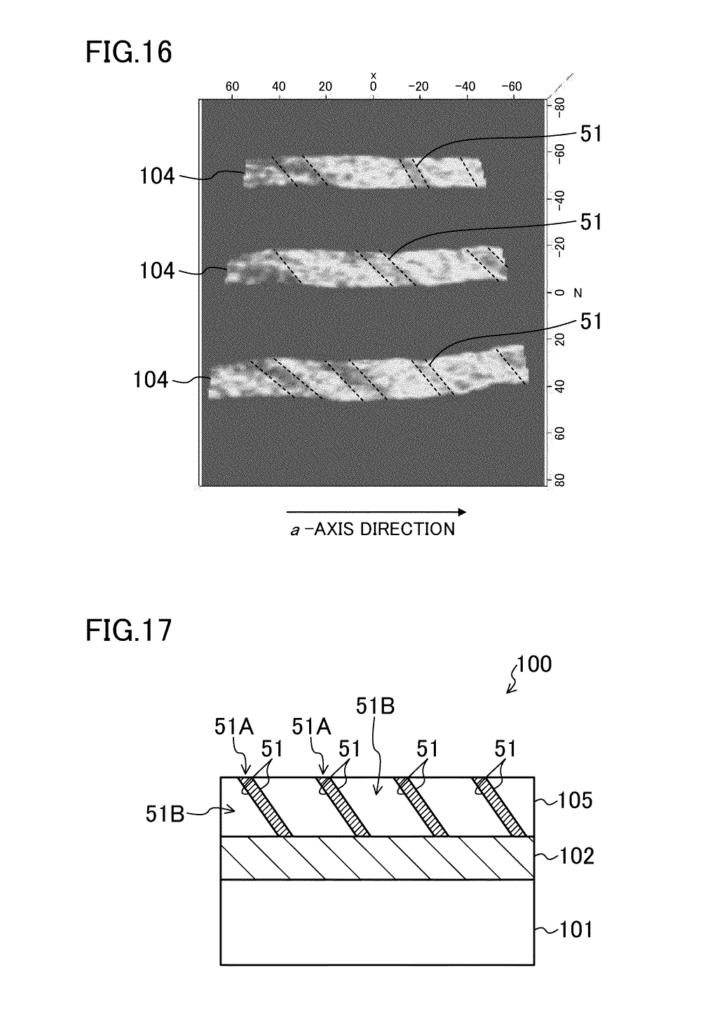

FIG. 16 illustrates the result of observing the In composition distribution of the well layers 104 of FIG. 13, each of which has been formed of m-plane In_{0.09}Ga_{0.91}N with an emission wavelength of 407 nm.

The light-emitting device 100 including well layers 104 formed of m-plane In_{0.09}Ga_{0.91}N is hereinafter referred to as the light-emitting device 100 according to a first embodiment.

The well layers 104 formed of m-plane In_{0.09}Ga_{0.91}N with the emission wavelength of 407 nm were obtained under the following growth condition. The pressure was 500 Ton (1 Torr≈133.3 Pa). The growth rate was about 6.0 nm/min. The molar ratio of In supply was 0.30. The growth temperature was 735° C. Furthermore, the crystal growth was performed at a significantly high V/III ratio of 18387.

Atom probe images of FIG. 16 illustrates the result of observing the cross-section parallel to the c-plane with the a-axis of the well layers 104 formed of m-plane In_{0.09}Ga_{0.91}N with an emission wavelength of 407 nm identical with the horizontal axis. In FIG. 16, the In concentration distribution is visible at each 1% pitch from 3% to 12%. As shown in FIG. 16, relatively white regions with great contrast correspond to high In concentration regions. The relatively dark ash region corresponds to low In concentration regions. It is apparent from FIG. 16 that the In concentration distribution is clearly segmented by the low In concentration regions (the broken lines are added). The high In concentration regions mainly contribute to light emission. The low In concentration regions have lower In concentration than the high In concentration regions. Each of the high In concentration regions and the low In concentration regions is a layer. Each low In concentration region is thinner than each high In concentration region. The present inventors define the planes segmenting the low In concentration regions from the high In concentration regions as low In concentration planes 51.

The plurality of low In concentration planes 51 formed in the first embodiment exist along the a-axis direction, and inclined from the principal surfaces, which are growth surfaces of the well layers 104 toward the a-axis direction. The angle between each low In concentration plane 51 and the principal surface of the corresponding well layer 104 is about 60°. That is, the layer-like low In concentration regions are inclined from the principal surfaces of the well layers 104 at the angle of about 60°. The angle is identical with the angle of the slip plane in the well layers 104 formed by the m-plane growth, the slip plane is an m-plane different from the m-plane being the growth surface. The plane in which the non-luminescent center of point defects in the impurities of oxygen is interposed between two of the low In concentration planes 51 and contained in the low In concentration region.

It is believed that each low In concentration regions is provided to include the plane in which the non-luminescent center is generated, thereby forming an energy barrier to reduce a recombination trap of the carriers to the non-luminescent center. In the nitride semiconductor layer, since the bandgap increases with a decrease in the In concentration, the bandgap of the low In concentration regions is wider than the bandgap of the high In concentration regions.

In the atom probe microscopy shown in FIG. 16, since the scan region has a diameter of about 100 nm and several low In concentration regions exist in the scan region, the distance between the low In concentration regions is about tens of nm. The distance of about this extent is preferable. The width of each low In concentration region preferably ranges from about several nm to about dozen nm. For example, the distance between the low In concentration regions is not less than 10 nm and not more than 100 nm, and the width of each low In concentration region is not less than 1 nm and not more than 20 nm.

FIG. 17 schematically illustrates the cross-sectional structure of the semiconductor light-emitting device 100 according to the first embodiment.

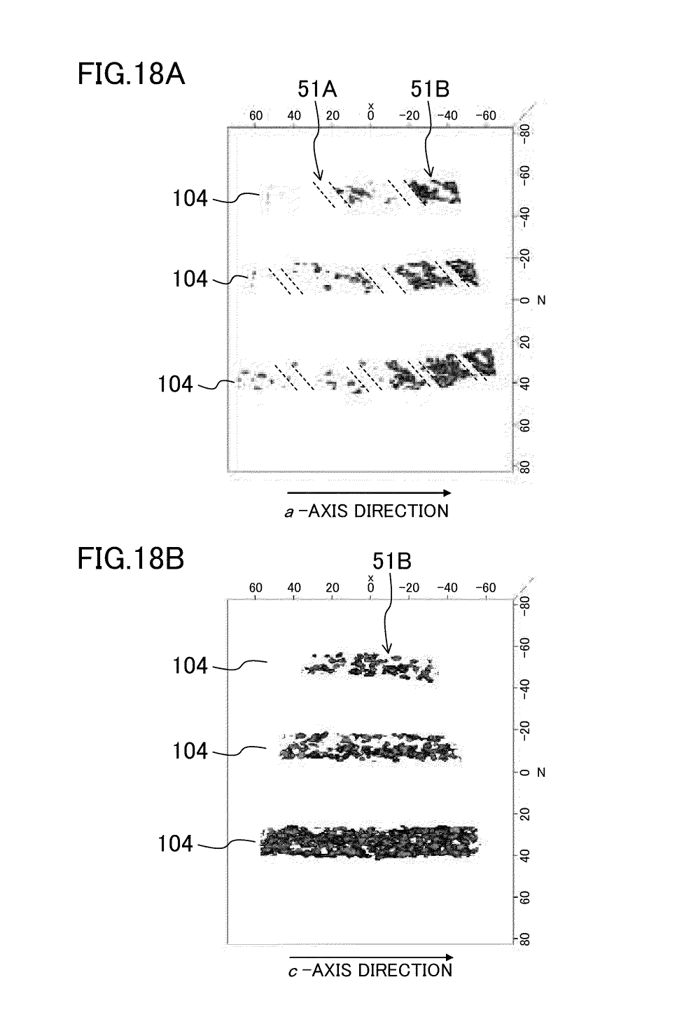

FIG. 18A illustrates a result of actually measuring the cross-section parallel to the c-plane of the light-emitting layer 105. In this measurement, only the regions with an In concentration of 9% are extracted by the atom probe microscope. The In concentration contributing to emission of light with a wavelength of 407 nm is estimated at 9% (an In composition of 0.09). As shown in FIG. 18A, in the cross-section parallel to the c-plane, high In concentration regions 51B contributing to light emission are formed in an oblique rhombus or a parallelogram. Each of the high In concentration regions 51B is clearly segmented by a low In concentration region 51A having an In concentration (i.e., an In composition) lower than the high In concentration region 51B (the broken lines added). That is, one or more high In concentration regions 51B and one or more low In concentration regions 51A are arranged alternately in the a-axis direction. The In concentration changes in the a-axis direction.

FIG. 18B illustrates a result of actually measuring the cross-section parallel to the a-plane of the light-emitting layer 105. FIG. 18B illustrates a result of actually measuring extracting the regions contributing to emission of light with a wavelength of 407 nm, i.e., the region with an In concentration of 9%, by the atom probe microscopy result. It is found from FIG. 18B that the high In concentration regions 51B contributing to light emission are distributed uniformly in the c-axis direction. If the cross-section parallel to the a-plane includes the low In concentration region 51A, the low In concentration region 51A has a fine line structure extending in the c-axis direction. That is, the low In concentration region 51 A is inclined in the a-axis direction, and is formed in a band extending in the c-axis. If the cross-section parallel to the a-plane includes the high In concentration region 51B, the high In concentration region 51B has a fine line structure extending in the c-axis direction.

The difference in the In concentration between the low In concentration regions 51A, which substantially serve as barrier layers, and the high In concentration regions 51B, which substantially contribute to light emission, will be described. From the result of observation with the atom probe microscope, the In composition in the low In concentration regions 51A is estimated to be not less than about 50% and not more than about 80% of the In composition in the high In concentration regions 51B.

For example, in the first embodiment using the emission wavelength of 407 nm, when the In composition in the high In concentration regions 51B is 0.09, the In composition in the low In concentration regions 51A ranges from about 0.05 to about 0.07.

For reference, in using an emission wavelength of 435 nm, where the In composition in a high In concentration region is 0.13, the In composition in a low In concentration region ranges from about 0.08 to about 0.10. In using an emission wavelength of 550 nm, where the In composition in a high In concentration region is 0.30, the In composition in a low In concentration region ranges from about 0.15 to about 0.24.

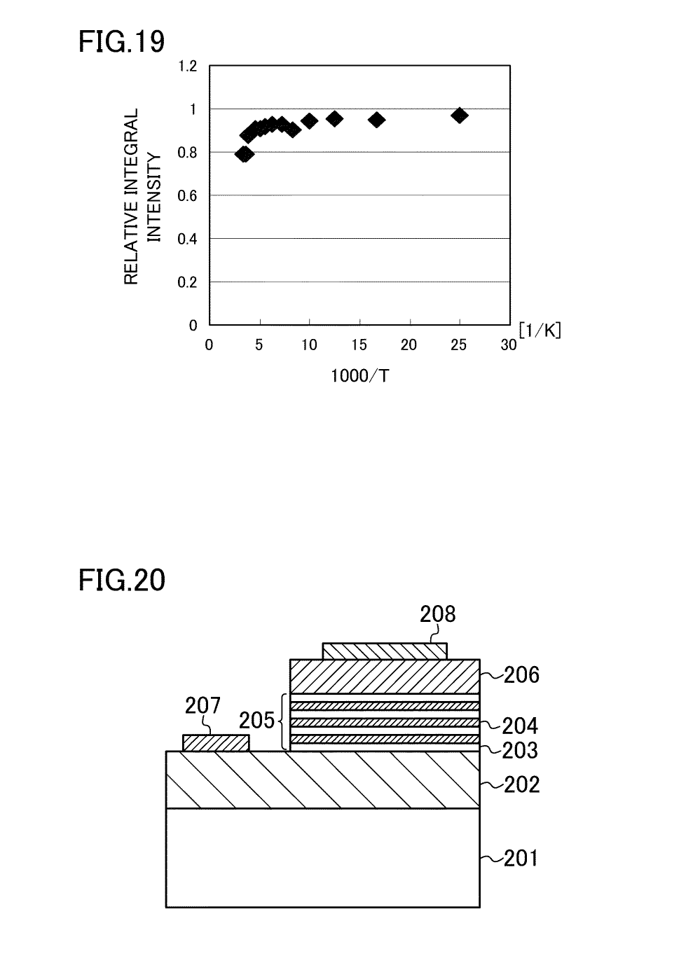

FIG. 19 illustrates a result of calculating the internal quantum efficiency of the light-emitting layer 105 obtained under the growth condition according to the first embodiment. The internal quantum efficiency is obtained by measuring the temperature characteristics ranging from 10 K to 300 K by PL. As shown in FIG. 19, the internal quantum efficiency of the light-emitting device 100 according to the first embodiment including the light-emitting layer 105 is not less than about 80%. That is, the first embodiment is advantageous in improving the internal quantum efficiency to about 1.2 times the internal quantum efficiency 66% under the conventional growth condition.

In the first embodiment, an example has been described where each light-emitting layer (i.e., each well layer) has the m-plane or the a-plane being a non-polar plane as a growth surface. Instead, the advantage of this embodiment can be obtained by using, for example, the r-plane, the (11-22) plane, or the (20-21) plane being a semi-polar plane.

In the case where the growth surface is a semi-polar plane, the interface between each low In concentration region and the corresponding high In concentration region is inclined in the direction of one of the two axes in the growth surface, which contains a component of the c-axis direction. In addition, the interface between the low In concentration region and the high In concentration region may be parallel to the c-plane. The In composition is constant in the in-plane direction defined by the other axis of the two axes containing no component of the c-axis direction.

In short, each low In concentration region is inclined in one of the axis direction in the growth surface, and in a band shape extending along the other axis direction.

More specifically, in the case where the growth surface is the semi-polar (11-22) plane, the interface between the different concentrations of the In composition is inclined in the [-1-123] axis direction, the concentration of the In composition is constant in the m-axis direction. In the case where the growth surface is the semi-polar (20-21) plane, the interface between the different concentrations of the In composition is inclined in the [10-1-4] axis direction, and the concentration of the In composition is constant in the a-axis direction. In the case where the growth surface in the semi-polar (1-102) plane, which is the r-plane, the interface between the different concentrations of the In composition is inclined in the [1-101] axis direction, and the concentration of the In composition is constant in the a-axis direction.

Therefore, in the case where the growth surface is a semi-polar plane, the slip plane is the c-plane, and the low In concentration surface or the low In concentration regions are formed along the c-plane.

The intake efficiency of In changes depending on the plane orientation of the principal surface. Thus, the significantly high V/III ratio and the molar ratio of In supply may change due to the difference in the intake efficiency of In depending on the principal surface being a non-polar plane and a semi-polar plane having various plane orientations. The significantly high V/III ratio and the molar ratio of In supply also depend on the crystal growth device. Therefore, the growth condition employed in the first embodiment is not limited to what has been described above.

The first embodiment may be modified or changed within the spirit and the scope of the present disclosure defined by the following claims. Therefore, the description of this embodiment is illustrative only and should not be taken as limiting our invention.

### Second Embodiment

A light-emitting diode (LED) device according to a second embodiment, which is a gallium nitride (GaN)-based compound semiconductor light-emitting device, will be described below with reference to FIG. 20.

The structure of the LED device shown in FIG. 20 will be described together with a manufacturing method.

In the second embodiment, a substrate 201 for crystal growth is used, on which gallium nitride (GaN) having a principal surface having a plane orientation of the (10-10) plane (i.e., the m-plane), can be grown. The substrate 201 is most preferably a free-standing substrate formed of gallium nitride and having an m-plane as a principal surface. Instead, the substrate may be formed of 4H- or 6H-silicon carbide (SiC) having a lattice constant close to that of GaN, and may expose an m-plane. It may be a sapphire substrate exposing the m-plane. In the case where the substrate 201 is formed of a material different from GaN-based semiconductor, a proper intermediate layer or a proper buffer layer is provided between the principal surface and the GaN-based semiconductor layer.

The above-described MOCVD is used to grow the GaN-based compound semiconductor including the InₓGa₁₋ₓN layer, where 0<x<1.

First, the substrate 201 is cleaned with buffered hydrogen fluoride (BHF), then, sufficiently washed with water, and dried. After the cleaning, the substrate 201 is put into a reaction chamber of an MOCVD apparatus without being exposed to the air as much as possible. After that, the substrate 201 is heated to a temperature 850° C. while ammonia (NH₃) gas being the nitrogen source, and hydrogen (H₂) gas and nitride (N₂) gas being carrier gas are supplied to the reaction chamber to clean the surface of the substrate 201.

Then, for example, TMG gas and silane (SiH₄) gas are supplied to the reaction chamber, and the substrate 201 is heated at 1100° C. to grow an n-GaN layer 202 on the substrate 201. The silane gas is material gas supplying silicon (Si) which is n-type dopant. The n-GaN layer 202 is grown at a growth rate ranging from about 10.0 nm/min to about 40.0 nm/min.

Next, the supply of the TMG gas and the SiH₄ gas being the group III material gas is stopped. As the carrier gas, the hydrogen gas is stopped and only the nitrogen gas is supplied. Then, the substrate temperature is reduced to the growth temperature 770° C., which is the most suitable growth condition in this embodiment and the saturation point, to grow one of the barrier layers 203 formed of GaN on the n-GaN layer 202.

After that, the supply of the trimethylindium (TMI) gas is started to grow one of the well layers 204 formed of InₓGa₁₋ₓN on the barrier layer 203. At this time, as the growth condition, the molar ratio of In supply is set to 0.60, which is obtained from the expression [TMI]/([TMI]+[TMG]). Three pairs of the barrier layer 203 and the well layer 204 are grown to form a light-emitting layer 205 having a multiple quantum well structure formed of GaN/InGaN. Each barrier layer 203 has a thickness of 30 nm, and each well layer 204 has a thickness of 15 nm.

Next, after forming the light-emitting layer 205, the supply of the TMG gas is stopped, and the supply of bis(cyclopentadienyl)magnesium (Cp₂Mg) gas, which is a material gas containing Mg as the p-type dopant, is started at a growth temperature raised to 1000° C. This grows a p-GaN layer 206 on the light-emitting layer 205.

Then, the substrate 201 grown up to the p-GaN layer 206 is extracted from the reaction chamber. After that, predetermined regions of the p-GaN layer 206 and the light-emitting layer 205 are removed by lithography, and etching, thereby exposing part of the n-GaN layer 202. An n-type electrode 207 formed of titanium (Ti)/aluminum (Al) is selectively formed in the region exposing the n-GaN layer 202. Then, a p-type electrode 208 formed of nickel (Ni)/gold (Au), etc., is selectively formed in the predetermined region of the p-GaN layer 206. The order of forming the n-type electrode 207 and the p-type electrode 208 is not the issue.

The LED device shown in FIG. 20 can be fabricated by the above-described manufacturing method.

Next, the operating characteristics of an LED device formed by the above-described manufacturing method will be described.

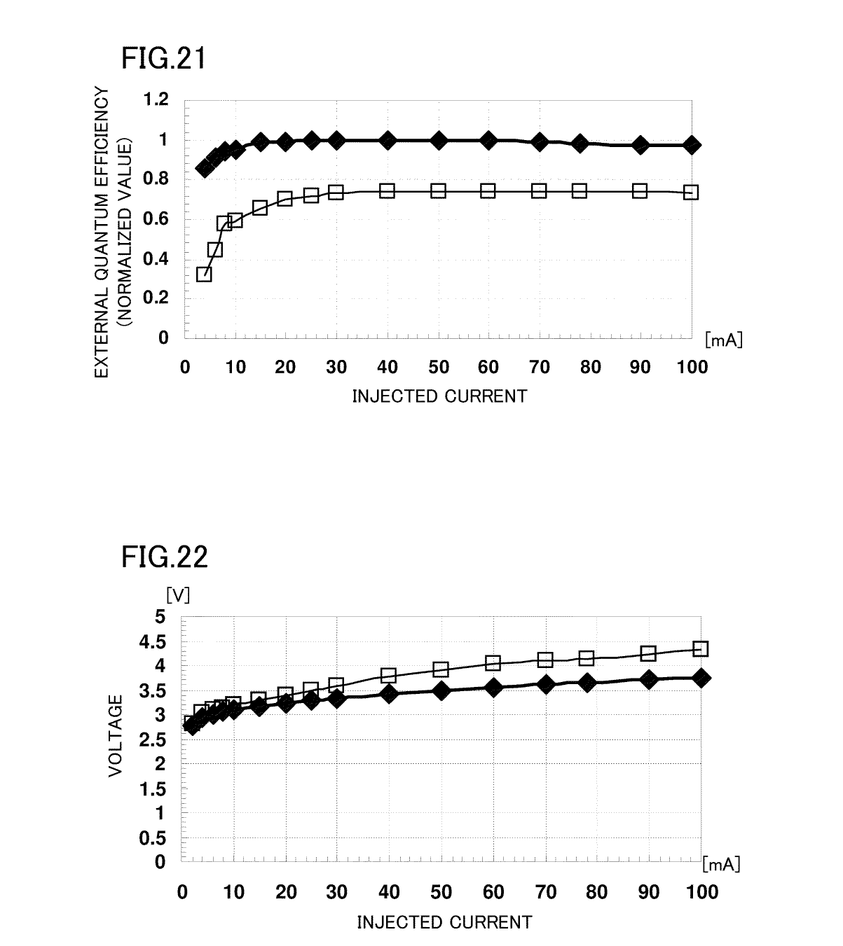

FIG. 21 illustrates the characteristics of the LED device according to the second embodiment, which are represented by black diamonds, and the characteristics of the comparison example, which are represented by white squares. In the graph, the horizontal axis represents an injected current, and the vertical axis represents the normalized value (EQE/EQEₘₐₓ) of the external quantum efficiency (EQE). FIG. 22 illustrates the operating characteristics of the LED device according to the second embodiment, which are represented by black diamonds, and the characteristics of the comparison example, which are represented by white squares. In the graph, the horizontal axis represents an injected current, and the vertical axis represents an operating voltage.

The difference between the second embodiment and the comparison example is merely as follows. In the comparison example, the active layer is formed under the conventional condition for the above-described internal quantum efficiency of about 66%. That is, in the comparison example, the well layers formed of InₓGa₁₋ₓN are formed under the following growth condition. The growth temperature is 755° C. The molar ratio of In supply [TMI]/([TMI]+[TMG]) is 0.50. The V/III ratio is 5500.

From the foregoing, as shown in FIGS. 21 and 22, a light-emitting device (LED device) including the well layers 204 formed of the m-plane InₓGa₁₋ₓN according to the second embodiment is significantly effective.

In each of the light-emitting devices of the first embodiment and the second embodiment, the emission wavelength is not limited to the short wavelength. The embodiments can be also implemented in a long-wavelength region having a higher In composition than the case of the short-wavelength. Specifically, the emission wavelength is not limited to the range around 400 nm, and the growth condition of the InₓGa₁₋ₓN layer can be optimized in a wide range of the emission wavelength up to about 520 nm.

### Variation of Second Embodiment

A variation of the second embodiment will be described hereinafter with reference to the drawings.

The upper surface (i.e., the principal surface) of an m-plane semiconductor layer is not necessarily a complete m-plane in an actual case, and may be inclined from the m-plane at a slight angle is, for example, more than 0° and less than ±1°. A substrate or a semiconductor layer having an upper surface of a complete m-plane is significantly difficult to form in view of the manufacturing technique. Thus, when an m-plane substrate or an m-plane semiconductor layer is formed by a current manufacturing technique, the actual upper surface is inclined from an ideal m-plane. The tilt angles and the orientations of the front surface vary depending on manufacturing steps, and are thus difficult to precisely control.

The upper surface (i.e., the principal surface) of the substrate or the semiconductor layer may be intentionally inclined from the m-plane at an angle not less than 1°.

In this variation, the upper surface (i.e., principal surface) of a GaN-based semiconductor layer is intentionally inclined from the m-plane at the angle not less than 1°. Except for this point, the LED device according to this variation has the same configuration as the LED device according to the second embodiment shown in FIG. 20.

In the LED device according to this variation, the principal surface of the substrate 201 shown in FIG. 20 is inclined from the m-plane at the angle not less than 1°. Such a substrate 201 is generally called an off-substrate. The off-substrate is fabricated in the step of slicing the surface from a single crystal ingot and polishing the front surface of the substrate so that the surface intentionally inclined from the m-plane to a specific direction is the principal surface. When the semiconductor layers are stacked on the principal surface of this inclined substrate, the upper surfaces (i.e., the principal surfaces) of the semiconductor layers are also inclined from the m-plane.

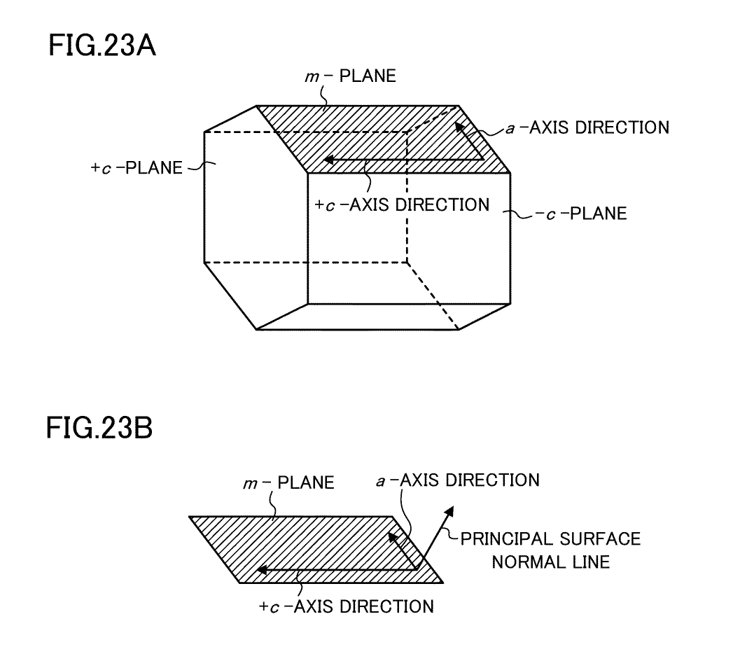

The tilt of the GaN-based compound semiconductor layer according to this variation will be described in detail with reference to FIGS. 23A and 23B.

FIG. 23A schematically illustrates the crystal structure (i.e., the wurtzite crystal structure) of GaN-based compound semiconductor. The orientation of the crystal structure shown in FIG. 2 is rotated 90°. The c-plane of GaN crystal is divided into a +c-plane and a −c-plane. The +c-plane is the (0001) plane with gallium (Ga) atoms appearing on the surface, and called a “Ga plane.” On the other hand, the −c-plane is a (000-1) plane with nitrogen (N) atoms appearing on the surface, and called an “N plane.” The +c-plane and the −c-plane are parallel to each other, and perpendicular to the m-plane. Since the c-plane has polarity, the c-plane is divided into the +c-plane and the −c-plane. There is no significance to divide a non-polar a-plane into a +a-plane and a −a-plane.

The +c-axis direction shown in FIG. 23A extends in perpendicular to the −c-plane and the +c-plane from the −c-plane to the +c-plane. On the other hand, the a-axis direction corresponds to the unit vector a₂ of FIG. 2, and faces the [-12-10] direction parallel to the m-plane. FIG. 23B is a perspective view illustrating the correlation among the normal line of the m-plane, the +c-axis direction, and the a-axis direction. The normal line of the m-plane is parallel to the [10-10] direction, and perpendicular to the both of the +c-axis direction and the a-axis direction as shown in FIG. 23B.

Therefore, the fact that the principal surface of a GaN-based semiconductor layer is inclined from the m-plane at the angle not less than 1° means that the normal line of the principal surface of the GaN-based semiconductor layer is inclined from the normal line of the m-plane at the angle not less than 1°.

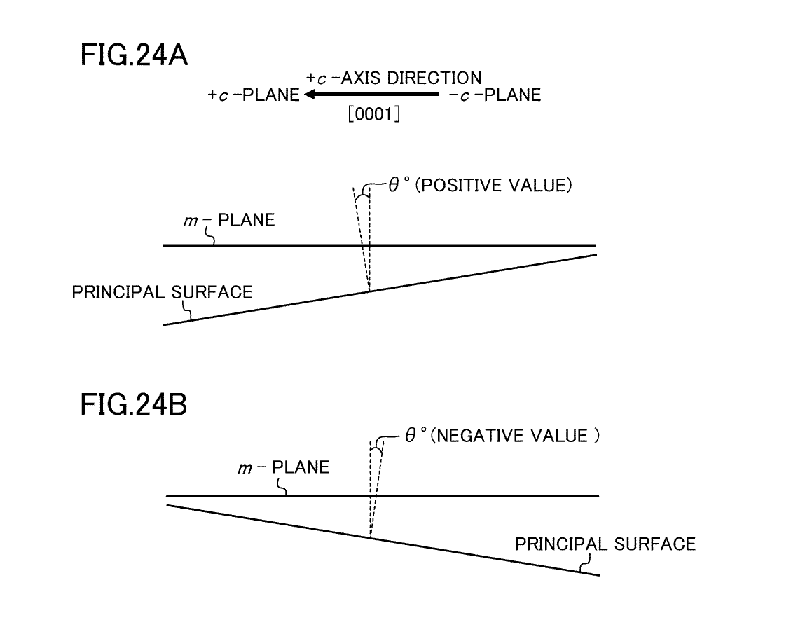

FIGS. 24A and 24B are cross-sectional views illustrating the relation between the principal surface and the m-plane of a GaN-based semiconductor layer. The cross-sectional direction is perpendicular to both of the m-plane and the c-plane. FIGS. 24A and 24B show arrows indicating the +c-axis direction. As shown in FIG. 23B, the m-plane is parallel to the +c-axis direction. Therefore, the normal line vector of the m-plane is perpendicular to the +c-axis direction.

In the examples shown in FIGS. 24A and 24B, the normal line vector of the principal surface of the GaN-based semiconductor layer is inclined from the normal line vector of the m-plane in the c-axis direction. More specifically, the normal line vector of the principal surface is inclined toward the +c-plane in the example of FIG. 24A, and toward the −c-plane in the example of FIG. 24B.

In this variation, the tilt angle (a tilt angle θ) of the normal line vector of the principal surface from the normal line vector of the m-plane in FIG. 24A has a positive value. The tilt angle θ in FIG. 24B has a negative value. In each case, the principal surface is inclined in the c-axis direction.

In this variation, where the tilt angle is not less than 1° and not more than 5°, or not less than −5° and not more than −1°, the advantages of the second embodiment can be obtained similar to the case where the tilt angle is more than 0° and less than ±1°.

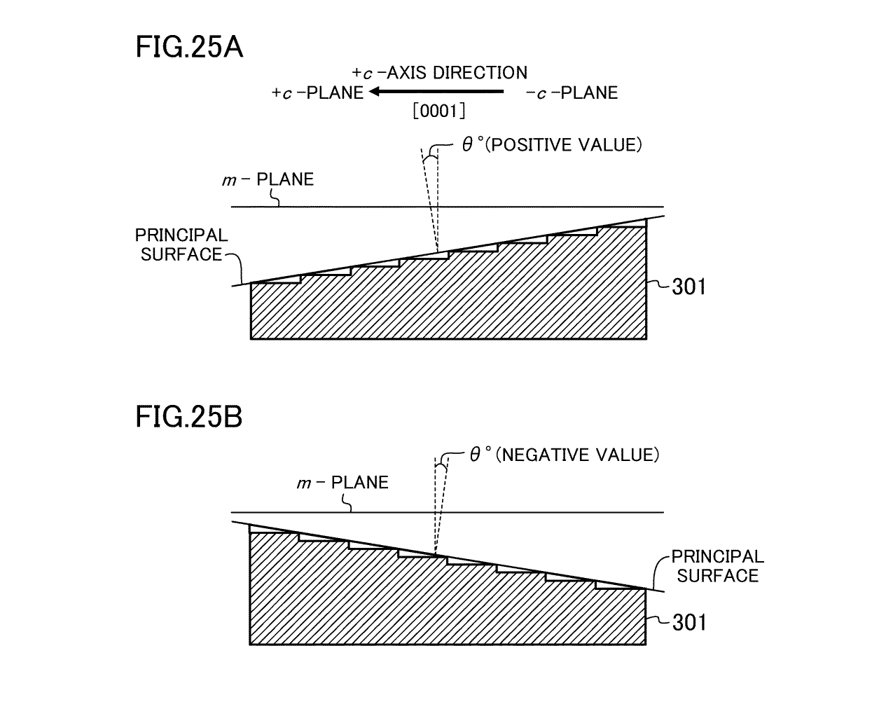

The reason why this variation can provide the advantages of the second embodiment will be described with reference to FIGS. 25A and 25B. FIGS. 25A and 25B illustrate cross-sectional structures corresponding to FIGS. 24A and 24B, respectively, and show the vicinity of the principal surface of a GaN-based semiconductor layer 301 inclined from the m-plane in the c-axis direction. Where the tilt angle θ is 5° or smaller, as shown in FIGS. 25A and 25B, a plurality of steps are formed in the principal surface of the GaN-based semiconductor layer 301. Each step has a height corresponding to a unit atom layer (i.e., 0.27 nm). The steps are arranged in parallel at almost even intervals (not less than 3 nm). This arrangement of the steps forms the principal surface inclined from the m-plane as a whole. However, microscopically, a plurality of regions having the m-plane are exposed as shown in the figures. The surface of the GaN-based semiconductor layer 301 having a principal surface of inclined from the m-plane has such structure, since the m-plane is originally significantly stable as a crystal plane. As such, the plurality of steps along the m-plane are formed.

A similar phenomenon occurs even when the tilt direction of the normal line vector of the principal surface is the plane orientation other than the +c-plane and the −c-plane. For example, even if the normal line vector of the principal surface is inclined in the a-axis or another direction, a similar phenomenon occurs as long as the tilt angle is not less than 1° and not more than 5°.

Therefore, even a GaN-based semiconductor layer with a principal surface inclined from the m-plane in a certain direction at an angle not less than 1° and not more than 5° provides the curved characteristic line shown in FIG. 12. As a result, this variation provides the advantages of the second embodiment.

As such, the absolute value of the tilt angle θ is 5° or smaller, thereby mitigating the reduction in the internal quantum efficiency caused by a piezoelectric field.

However, even if the tilt angle θ is, for example, 5°, the actual tilt angle θ may be shifted from the set value within the range from 5° to about ±1° due to variations in the manufacturing. These variations in the manufacturing are difficult to completely exclude. The shift of such a small angle does not reduce the advantages of this variation.

The principal surface of the GaN-based semiconductor layer 301 is not necessarily inclined from the m-plane. Even if the principal surface is inclined from the a-plane or the r-plane at an angle of 5° or smaller, the above-described step-terrace structure is formed, thereby providing the advantages of this variation.

As described above, the m-plane, the a-plane, the r-plane, the (11-22) plane, the (20-21) plane, the “non-polar plane,” or the “semi-polar plane” according to the present disclosure is not limited to the plane completely parallel to the crystal plane such as the m-plane, the a-plane, the r-plane, the (11-22) plane, or the (20-21) plane; but includes a plane inclined from the crystal plane at an angle of 5° or smaller.

The above-described variation of the second embodiment is also applicable to the first embodiment.

### Third Embodiment

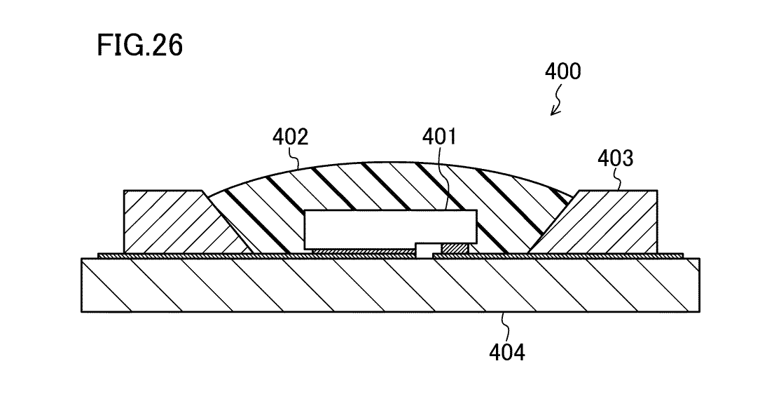

A third embodiment will be described hereinafter with reference to FIG. 26.

Each of the light-emitting devices according to the first embodiment, the second embodiment, and the variation itself may be used as a light source apparatus.

One of the light-emitting devices according to the embodiments and the variation may be combined with sealing resin, etc. containing fluorescent member performing wavelength conversion. This increases the emission wavelength band so that, for example, a white light source apparatus is formed.

FIG. 26 illustrates an example white light source apparatus. As shown in FIG. 26, a white light source apparatus 400 according to the third embodiment includes a light-emitting device 401, which is any one of the light-emitting devices according to the first embodiment, the second embodiment, and the variation, and a resin layer 402, in which a fluorescent material (e.g., yttrium aluminum garnet (YAG)) is dispersed. The fluorescent material converts the wavelength of the light emitted from the light-emitting device 401 to a longer wavelength.

The light-emitting device 401 is fixed to the top of, for example, a holding member 404 such as a package having the upper surface with a wiring pattern, while the substrate faces upward and the light-emitting layer faces downward, i.e., by what is called junction-down mounting. A reflective member 403 formed of for example, metal is located on the holding member 404 to surround the light-emitting device 401.

The resin layer 402 is formed on the holding member 404 inside the reflective member 403 to cover the light-emitting device 401.

As described above, the third embodiment provides the high efficient white light source apparatus 400.

The light-emitting devices according to the first embodiment, the second embodiment, the variation, and the third embodiment are applicable to light-emitting devices other than LED devices such as superluminescent diode (SLD) devices and semiconductor laser (LD) devices.

In each of the light-emitting devices according to the first embodiment, the second embodiment, the variation, and the third embodiment, since the portion of the light-emitting layer with a low In composition at the interface of the composition distribution serves as a barrier layer in the light-emitting layer. Thus, the impurities (e.g., oxygen) incorporated into the barrier layer serve as a non-luminescent center to mitigate the reduction in the luminous efficiency. As a result, the luminous efficiency of the active layer largely improves.

The gallium nitride (GaN)-based compound semiconductor light-emitting device and the light source apparatus using the device according to the present disclosure largely improve the luminous efficiency of an active layer, and are useful for, for example, high-luminance white LED light source apparatuses of next generation.

What is claimed is:

1. A gallium nitride-based compound semiconductor light-emitting device formed of nitride semiconductor expressed by a general expression AlₓIn_{y}Ga_{z}N, where 0≦x<1, 0<y<1, 0<z<1, and x+y+z=1, the device comprising:
a light-emitting layer having a growth surface of a non-polar plane or a semi-polar plane, wherein
a growth surface of the nitride semiconductor has two anisotropic axes,
an In composition of the nitride semiconductor has distribution changing along a first axis of the two axes,
an interface between a region with a low In composition and a region with a high In composition is inclined from a plane perpendicular to the first axis toward the growth surface of the nitride semiconductor, and
the region with the low In composition is formed along a slip plane to include the slip plane.

2. The device of claim 1, wherein
the In composition of the nitride semiconductor is uniform along a second axis of the two axes.

3. The device of claim 1, wherein
the growth surface of the nitride semiconductor has a plurality of steps along an m-plane.

4. The device of claim 1, wherein
the growth surface of the nitride semiconductor is an m-plane,
the first axis is along an a-axis direction, and
the second axis is along a c-axis direction.

5. The device of claim 1, wherein
the growth surface of the nitride semiconductor is the semi-polar plane, and
the first axis is along one of the two axes, which has a component of a c-axis direction.

6. The device of claim 1, wherein
the growth surface of the nitride semiconductor is a (11-22) plane,
the first axis is along a [-1-123] axis direction, and
the second axis is along an m-axis direction.

7. The device of claim 1, wherein
the growth surface of the nitride semiconductor is a (20-21) plane,
the first axis is along a [10-1-4] axis direction, and
the second axis is along an a-axis direction.

8. The device of claim 1, wherein
the growth surface of the nitride semiconductor is a (1-102) plane,
the first axis is along a [1-101] axis direction, and
the second axis is along an a-axis direction.

9. A gallium nitride-based compound semiconductor light-emitting device formed of nitride semiconductor expressed by a general expression AlₓIn_{y}Ga_{z}N, where 0≦x<1, 0<y<1, 0<z<1, and x+y+z=1, the device comprising:
a light-emitting layer having a growth surface of a non-polar plane or a semi-polar plane, wherein
the growth surface of the nitride semiconductor is an m-plane, and has two anisotropic axes,
a first axis of the two axes is along an a-axis direction,
a second axis of the two axes is along a c-axis direction,
an In composition of the nitride semiconductor has distribution changing along the first axis of the two axes, and
an interface between a region with a low In composition and a region with a high In composition is inclined from a plane perpendicular to the first axis toward the growth surface of the nitride semiconductor.

10. A gallium nitride-based compound semiconductor light-emitting device formed of nitride semiconductor expressed by a general expression AlₓIn_{y}Ga_{z}N, where 0≦x<1, 0<y<1, 0<z<1, and x+y+z=1, the device comprising:
a light-emitting layer having a growth surface of a non-polar plane or a semi-polar plane, wherein
the growth surface of the nitride semiconductor is an m-plane, and has two anisotropic axes,
a first axis of the two axes is along an a-axis direction,
a second axis of the two axes is along a c-axis direction,
the nitride semiconductor includes a low In concentration region having an In concentration lower than a high In concentration region contributing to light emission, and
the low In concentration region is inclined along the first axis, and is in a band-like shape extending along the second axis.

11. The device of claim 1, wherein
the In composition of the region with the low In concentration of the nitride semiconductor is not higher than 80% of the In composition of the region with the high In composition.

12. The device of claim 10, wherein
the In composition of the region with the low In concentration of the nitride semiconductor is not higher than 80% of the In composition of the region with the high In composition.

13. The device of claim 11, wherein
the In composition of the region with the low In concentration of the nitride semiconductor is not higher than 80% of the In composition of the region with the high In composition.

14. The device of claim 1, wherein
the In composition of the region with the low In concentration of the nitride semiconductor is not less than 50% and not more than 80% of the In composition of the region with the high In composition.

15. The device of claim 10, wherein
the In composition of the region with the low In concentration of the nitride semiconductor is not less than 50% and not more than 80% of the In composition of the region with the high In composition.

16. The device of claim 11, wherein
the In composition of the region with the low In concentration of the nitride semiconductor is not less than 50% and not more than 80% of the In composition of the region with the high In composition.

17. The device of claim 1, wherein
the light-emitting layer is at least one quantum well layer.

18. The device of claim 10, wherein
the light-emitting layer is at least one quantum well layer.

19. The device of claim 11, wherein
the light-emitting layer is at least one quantum well layer.

20. The device of claim 18, wherein
the quantum well layer has a thickness not less than 2 nm and not more than 20 nm.

21. The device of claim 18, wherein
the quantum well layer has a thickness not less than 6 nm and not more than 16 nm.

22. The device of claim 1, wherein
the region with the low In composition includes a plurality of regions each having the low In composition,
the low In concentration region includes a plurality of low In concentration regions,
a distance between a pair of the regions with the low In composition or between a pair of the low In concentration regions is not less than 10 nm and not more than 100 nm, and
a width of the region with the low In composition or a width of the low In concentration region is not less than 1 nm and not more than 20 nm.

23. The device of claim 10, wherein
the region with the low In composition includes a plurality of regions with the low In composition,
the low In concentration region includes a plurality of low In concentration regions,
a distance between a pair of the regions with the low In composition or between a pair of the low In concentration regions is not less than 10 nm and not more than 100 nm, and
a width of the region with the low In composition or a width of the low In concentration region is not less than 1 nm and not more than 20 nm.

24. The device of claim 11, wherein
the region with the low In composition includes a plurality of regions with the low In composition,
the low In concentration region includes a plurality of low In concentration regions,
a distance between a pair of the regions with the low In composition or between a pair of the low In concentration regions is not less than 10 nm and not more than 100 nm, and
a width of the region with the low In composition or a width of the low In concentration region is not less than 1 nm and not more than 20 nm.

25. A light source apparatus comprising:
the gallium nitride-based compound semiconductor light-emitting device of claim 1; and
a wavelength converter including a fluorescent member converting a wavelength of light irradiated from the gallium nitride-based compound semiconductor light-emitting device.

26. A light source apparatus comprising:
the gallium nitride-based compound semiconductor light-emitting device of claim 10; and
a wavelength converter including a fluorescent member converting a wavelength of light irradiated from the gallium nitride-based compound semiconductor light-emitting device.

27. A light source apparatus comprising:
the gallium nitride-based compound semiconductor light-emitting device of claim 11; and
a wavelength converter including a fluorescent member converting a wavelength of light irradiated from the gallium nitride-based compound semiconductor light-emitting device.

28. The device of claim 1, wherein the region with the low In composition or the region with the high In composition has a fine line structure extending along the second axis of the two axes in a cross-section parallel to the second axis.
